(19) United States
(12) Patent Application Publication
(10) Pub. No.: US 2024/0194768 A1
(43) Pub. Date: Jun. 13, 2024

(54) INTEGRATED CIRCUIT DEVICE AND METHOD OF MANUFACTURING THE SAME

(71) Applicant: SAMSUNG ELECTRONICS CO., LTD., SUWON-SI (KR)

(72) Inventors: Gilhwan Son, Suwon-si (KR); Taegon Kim, Suwon-si (KR); Sihyung Lee, Suwon-si (KR); Jihye Yi, Suwon-si (KR)

(21) Appl. No.: 18/533,262

(22) Filed: Dec. 8, 2023

(30) Foreign Application Priority Data
Dec. 12, 2022 (KR) 10-2022-0173043

(51) Int. Cl. H01L 29/66; H01L 21/8234; H01L 27/088; H01L 29/20; H01L 29/78

(52) U.S. Cl. CPC H01L 29/66795; H01L 21/823431; H01L 27/0886; H01L 29/2003; H01L 29/66545; H01L 29/6656; H01L 29/785

(57) ABSTRACT

A method of manufacturing an integrated circuit device includes forming a preliminary channel stack, which includes sacrificial layers and channel layers, on a substrate, forming a preliminary channel pattern and a fin-type active region by removing a portion of the preliminary channel stack and a portion of the substrate to define a buried trench, forming a sacrificial buried layer in the buried trench, forming a source/drain region on the fin-type active region, forming, on the sacrificial buried layer, a power via electrically connected to the source/drain region, removing a portion of the substrate to expose a bottom surface of the sacrificial buried layer, removing the sacrificial buried layer and forming, in the buried trench, a backside buried wiring layer connected to the power via, and forming a backside wiring structure electrically connected to the backside buried wiring layer.

### CROSS-REFERENCE TO RELATED APPLICATION

This U.S. patent application claims priority under 35 U.S.C. § 119 to Korean Patent Application No. 10-2022-0173043, filed on Dec. 12, 2022, in the Korean Intellectual Property Office, the disclosure of which is incorporated by reference in its entirety herein.

### 1. TECHNICAL FIELD

The inventive concept relates to an integrated circuit device and a method of manufacturing the integrated circuit device, and more particularly, to an integrated circuit device including a field-effect transistor and a method of manufacturing the integrated circuit device.

### 2. DISCUSSION OF RELATED ART

High-capacity integrated circuits (e.g., chips) are needed since electronic products need to be small and multifunctional. Small-sized field-effect transistors (FETs) may be used to reduce the size of integrated circuits. However, such small-sized FETs have complex wiring structures that may result in decreased operation speeds.

A backside power delivery network (BSPDN) may be used to increase the performance of a chip by arranging a signal wiring line on a front side of the chip and arranging a power wiring line on a back side of the chip. However, use of the BSPDN makes it difficult to perform high-aspect ratio etching and metal filling processes.

### SUMMARY

An embodiment of the inventive concept provides an integrated circuit device including field-effect transistors having an increased degree of integration and performance by employing a backside power wiring structure, and a method of manufacturing the integrated circuit device.

According to an aspect of the inventive concept, there is provided a method of manufacturing an integrated circuit device, the method including forming a preliminary channel stack, which includes a plurality of sacrificial layers and a plurality of channel layers, on a substrate including a first surface and a second surface opposite to the first surface, forming a preliminary channel pattern and a fin-type active region by removing a portion of the preliminary channel stack and a portion of the substrate, wherein a sidewall of the preliminary channel pattern and a sidewall of the fin-type active region are aligned with each other to define a buried trench, forming a sacrificial buried layer in the buried trench, forming a source/drain region on the fin-type active region, forming a power via on the sacrificial buried layer, the power via being electrically connected to the source/drain region, removing a portion of the substrate from the second surface of the substrate to expose a bottom surface of the sacrificial buried layer, removing the sacrificial buried layer and forming a backside buried wiring layer in the buried trench, the backside buried wiring layer being electrically connected to the power via, and forming a backside wiring structure on the second surface of the substrate, the backside wiring structure being electrically connected to the backside buried wiring layer.

According to an aspect of the inventive concept, there is provided a method of manufacturing an integrated circuit device, the method including forming a device isolation trench by removing a portion of a substrate, and forming a fin-type active region from the substrate to extend in a first horizontal direction, wherein the substrate includes a first surface and a second surface opposite to the first surface, forming a buried trench by removing a portion of the substrate at a bottom of the device isolation trench, wherein a sidewall of the buried trench is aligned with a sidewall of the fin-type active region, forming a sacrificial buried layer in the buried trench, forming a gate electrode on the fin-type active region to extend in a second horizontal direction intersecting with the first horizontal direction, forming a source/drain region on a portion of the fin-type active region, which is arranged on one side of the gate electrode, forming a power via on the sacrificial buried layer, the power via being electrically connected to the source/drain region, removing a portion of the substrate from the second surface of the substrate to expose a bottom surface of the sacrificial buried layer, removing the sacrificial buried layer and forming a backside buried wiring layer in the buried trench, the backside buried wiring layer being connected to the power via, and forming a backside wiring structure on the second surface of the substrate, the backside wiring structure being electrically connected to the backside buried wiring layer.

According to an aspect of the inventive concept, there is provided a method of manufacturing an integrated circuit device, the method including forming a preliminary channel stack, which includes a plurality of sacrificial layers and a plurality of channel layers, on a substrate including a first surface and a second surface opposite to the first surface, forming a preliminary channel pattern and a fin-type active region by removing a portion of the preliminary channel stack and a portion of the substrate to form a device isolation trench, forming a buried trench by removing a portion of the substrate, which is at a bottom of the device isolation trench, wherein a sidewall of the buried trench is aligned with a sidewall of the fin-type active region, forming an insulating liner on an inner wall of each of the device isolation trench and the buried trench, forming a sacrificial buried layer in the buried trench, wherein the sacrificial buried layer is not positioned on the inner wall of the device isolation trench, forming a buried insulating layer on the sacrificial buried layer and on the inner wall of the device isolation trench, forming a source/drain region on a portion of the fin-type active region, forming a power via on the sacrificial buried layer, the power via being electrically connected to the source/drain region, removing a portion of the substrate from the second surface of the substrate to expose a bottom surface of the sacrificial buried layer, removing the sacrificial buried layer and forming a backside buried wiring layer in the buried trench, the backside buried wiring layer being electrically connected to the power via, and forming a backside wiring structure on the second surface of the substrate, the backside wiring structure being electrically connected to the backside buried wiring layer.

### BRIEF DESCRIPTION OF THE DRAWINGS

Embodiments will be more clearly understood from the following detailed description taken in conjunction with the accompanying drawings in which:

FIG. 1 is a schematic layout diagram illustrating an integrated circuit device according to an embodiment;

FIG. 2 is an enlarged layout diagram of a region II of FIG. 1;

FIG. 3 is a cross-sectional view of the integrated circuit device, taken along a line A1-A1′ of FIG. 2;

FIG. 4 is a cross-sectional view of the integrated circuit device, taken along a line B1-B1′ of FIG. 2;

FIG. 5 is a cross-sectional view of the integrated circuit device, taken along a line B2-B2′ of FIG. 2;

FIGS. 6 and 7 are cross-sectional views of an integrated circuit device according to an embodiment;

FIG. 8 is a cross-sectional view illustrating an integrated circuit device according to an embodiment;

FIGS. 9 to 20 are cross-sectional views illustrating a method of manufacturing an integrated circuit device, according to an embodiment, and in particular, FIGS. 9, 14A, 15A, and 16A are cross-sectional views each corresponding to a cross-section taken along the line A1-A1′ of FIG. 2, FIGS. 10A, 14B, 15B, 16B, and 17A are cross-sectional views each corresponding to a cross-section taken along the line B1-B1′ of FIG. 2, and FIGS. 10B, 11, 12, 13, 15C, 17B, 18, 19, and 20 are cross-sectional views each corresponding to a cross-section taken along the line B2-B2′ of FIG. 2;

FIGS. 21 to 24 are cross-sectional views illustrating a method of manufacturing an integrated circuit device, according to an embodiment, and in particular, FIGS. 21 to 24 are cross-sectional views each corresponding to a cross-section taken along the line B2-B2′ of FIG. 2;

FIG. 25 is a block diagram illustrating a system-on-chip (SoC) according to an embodiment; and

FIG. 26 is a block diagram illustrating a computing system that includes memory storing a program, according to an embodiment.

### DETAILED DESCRIPTION OF THE EMBODIMENTS

Hereinafter, embodiments of the inventive concept will be described in detail with reference to the accompanying drawings.

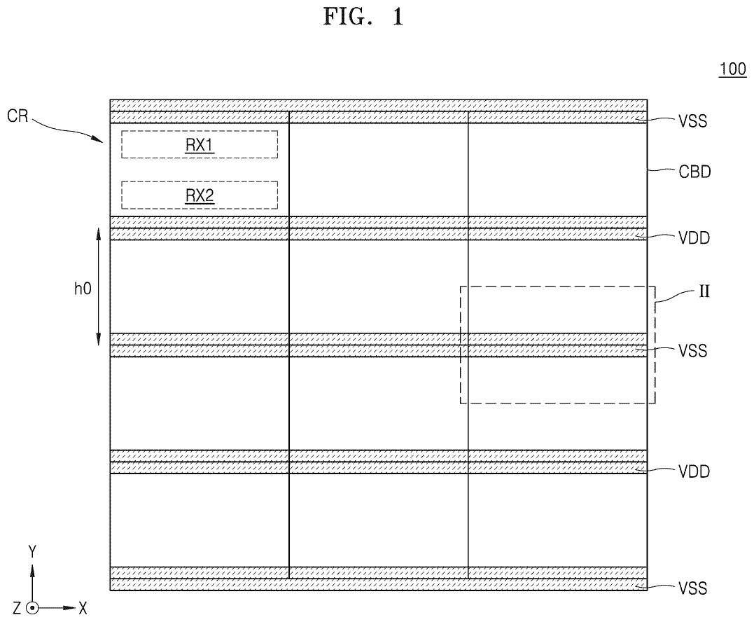

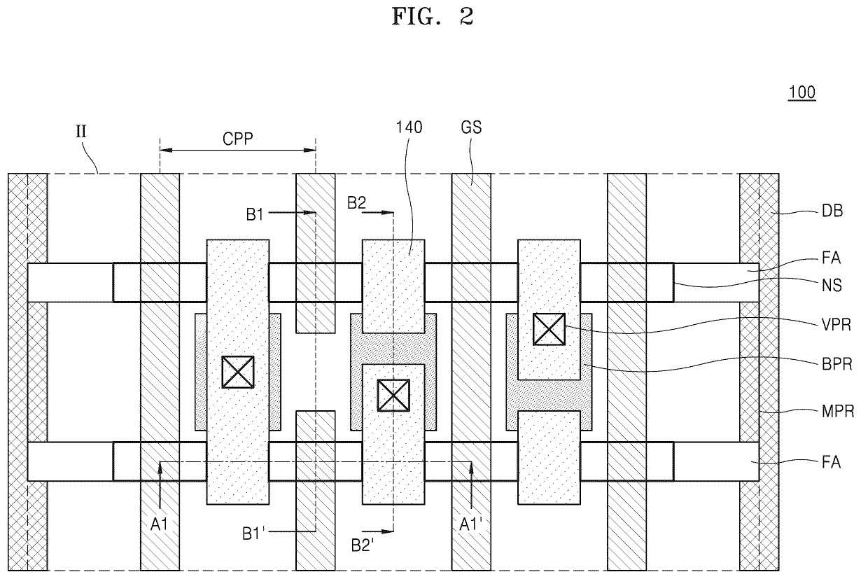

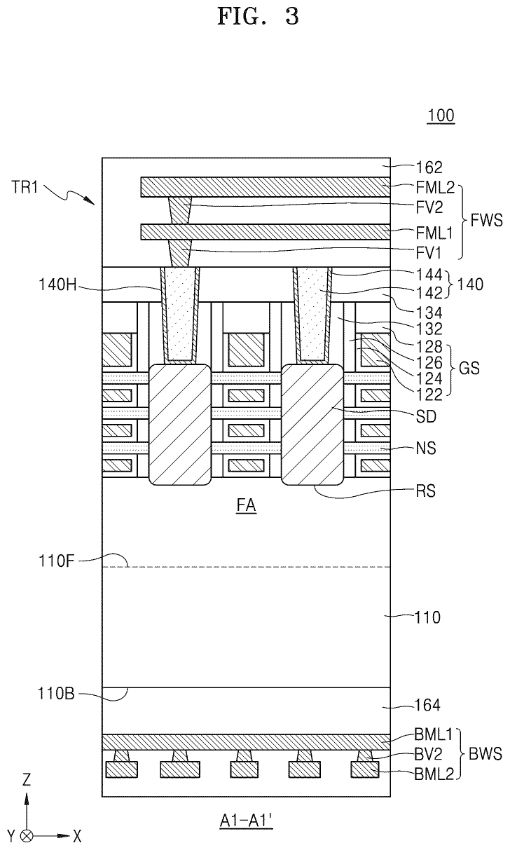

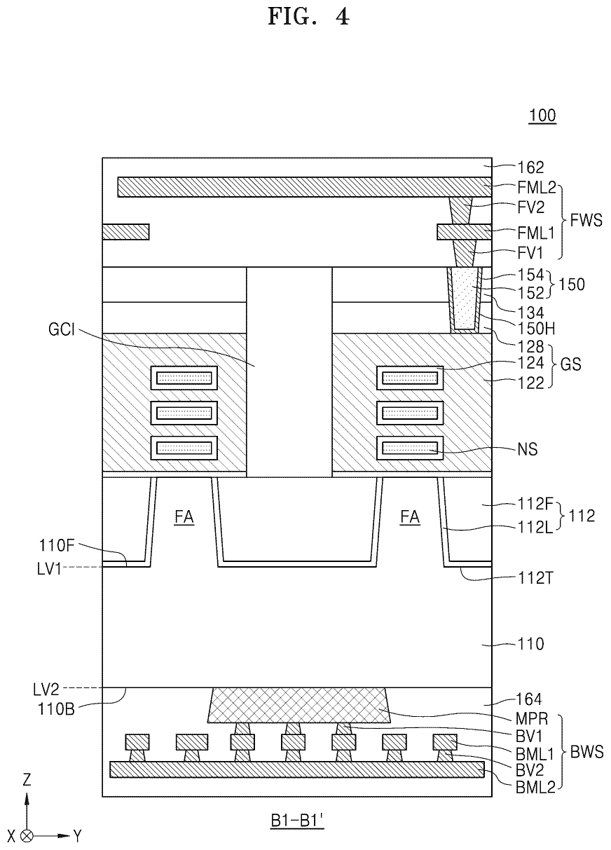

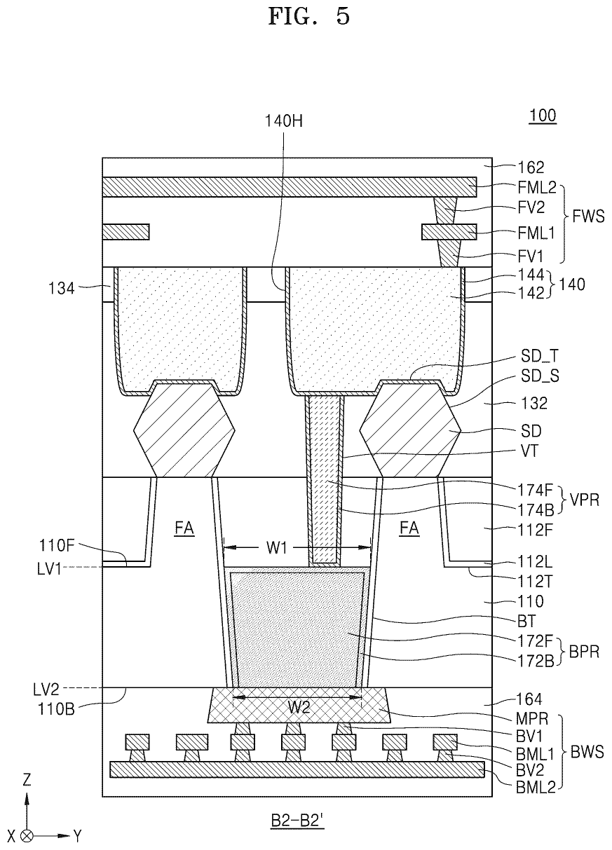

FIG. 1 is a schematic layout diagram illustrating an integrated circuit device 100 according to some embodiments. FIG. 2 is an enlarged layout diagram of a region II of FIG. 1. FIG. 3 is a cross-sectional view of the integrated circuit device 100, taken along a line A1-A1′ of FIG. 2, FIG. 4 is a cross-sectional view of the integrated circuit device 100, taken along a line B1-B1′ of FIG. 2, and FIG. 5 is a cross-sectional view of the integrated circuit device 100, taken along a line B2-B2′ of FIG. 2.

Referring to FIGS. 1 to 5, the integrated circuit device 100 may include a plurality of cells CR arranged on a first surface 110F of a substrate 110, and a backside wiring structure BWS arranged on a second surface 110B of the substrate 110. The plurality of cells CR may be arranged in a matrix form in a first horizontal direction (X direction) and a second horizontal direction (Y direction), which are parallel to the first surface 110F of the substrate 110. The plurality of cells CR may be areas in which various logic cells of a logic circuit are respectively arranged, respectively.

In examples shown in FIGS. 1 to 5, the integrated circuit device 100 may be used to implement a logic cell including a multi-bridge channel field-effect transistor (MBCFET) device. However, the inventive concept is not limited thereto. For example, the integrated circuit device 100 may include a planar FET device, a gate-all-around type FET device, a finFET device, an FET device that is based on a 2-dimensional material, such as an MoS₂ semiconductor gate electrode, or the like.

A plurality of ground lines VSS and a plurality of power lines VDD may extend in the first horizontal direction (X direction) on the first surface 110F of the substrate 110 and may be alternately arranged spaced apart from each other in the second horizontal direction (Y direction). Therefore, a cell boundary CBD of one cell CR in the second horizontal direction (Y direction) may be arranged to overlap one ground line VSS and one power line VDD. Here, a cell CR having a cell boundary CBD, which overlaps one ground line VSS and one power line VDD adjacent to the one ground line VSS, may be referred to as a single height cell. For example, a cell boundary CBD may be arranged between and contact one ground line VSS and one power line VDD. The cell CR, which is a single height cell, may have a first height h0 in the second horizontal direction (Y direction).

Each of the plurality of ground lines VSS and the plurality of power lines VDD may correspond to a main power rail MPR, which is included in the backside wiring structure BWS arranged on the second surface 110B of the substrate 110. The main power rail MPR may be connected to a source/drain region SD, which is arranged on the first surface 110F of the substrate 110, via a backside buried wiring layer BPR and a power via VPR. A power supply voltage and a ground voltage may be supplied from the backside wiring structure BWS to the source/drain region SD, which is arranged on the first surface 110F of the substrate 110, via the backside buried wiring layer BPR and the power via VPR.

The cell boundary CBD of each of the plurality of cells CR in the first horizontal direction (X direction) may be arranged to overlap a separation structure DB. The separation structure DB may extend in the second horizontal direction (Y direction) and may electrically insulate one cell CR from another cell CR adjacent to the one cell CR. The separation structure DB may be formed of an insulating material.

As shown in FIG. 1, the substrate 110 may include a first active region RX1 and a second active region RX2, which are spaced apart from each other in the second horizontal direction (Y direction). For example, each of the plurality of cells CR may include the first active region RX1 and the second active region RX2. Each of the plurality of cells CR may include a transistor TR1 formed on each of the first active region RX1 and the second active region RX2. For example, the transistor TR1 arranged on the first active region RX1 may be a p-channel metal-oxide semiconductor (PMOS) transistor, and the transistor TR1 arranged on the second active region RX2 may be a n-channel metal-oxide semiconductor (NMOS) transistor.

In some embodiments, the substrate 110 may include a Group IV semiconductor, such as Si or Ge, a Group IV-IV compound semiconductor, such as SiGe or SiC, or a Group III-V compound semiconductor, such as GaAs, InAs, or InP. A plurality of fin-type active regions FA may protrude from the first surface 110F of the substrate 110 and extend in the first horizontal direction (X direction) on the first surface 110F of the substrate 110. In an embodiment, one fin-type active region FA is arranged on the first active region RX1, and one fin-type active region FA is arranged on the second active region RX2.

A device isolation film 112 may be arranged on the first surface 110F of the substrate 110 to cover a lower portion of a sidewall of the fin-type active region FA. As shown in FIG. 5, the device isolation film 112 may extend from the first surface 110F of the substrate 110 to the inside of the substrate 110. The device isolation film 112 may at least partially cover the power via VPR or the backside buried wiring layer BPR. In an embodiment, the device isolation film 112 includes an insulating liner 112L and a buried insulating layer 112F. The insulating liner 112L may contact the first surface 110 and the buried insulating layer 112F may be disposed on the insulating liner 112L. The insulating liner 112L may be conformally formed to a relatively low thickness on an inner wall of a device isolation trench 112T, and the buried insulating layer 112F may be arranged on the insulating liner 112L to fill the inside of the device isolation trench 112T. For example, a portion of the substrate 100 may be removed to form the trench 112T.

In an embodiments, a plurality of semiconductor patterns NS are arranged over the fin-type active region FA to be spaced apart from each other in a vertical direction (Z direction). Each of the plurality of semiconductor patterns NS may include a Group IV semiconductor, such as Si or Ge, a Group IV-IV compound semiconductor, such as SiGe or SiC, or a Group III-V compound semiconductor, such as GaAs, InAs, or InP.

A plurality of gate structures GS may each extend in the second horizontal direction (Y direction) to surround the plurality of semiconductor patterns NS and may be arranged spaced apart from each other by as much as a first gate interval CPP in the first horizontal direction (X direction). Each of the plurality of gate structures GS may include a gate electrode 122, a gate insulating layer 124, a gate spacer 126, and a gate capping layer 128. The gate capping layer 128 may be disposed on the gate electrode 122. For example, the gate electrode 122 may extend in the second horizontal direction (Y direction) on the fin-type active region FA to surround the plurality of semiconductor patterns NS, and the gate insulating layer 124 may be arranged between the gate electrode 122 and the fin-type active region FA, between the gate electrode 122 and the device isolation film 112, and between the gate electrode 122 and each semiconductor pattern NS. The gate spacer 126 may be arranged on both sidewalls of the gate electrode 122, and the gate capping layer 128 may extend in the second horizontal direction (Y direction) on the gate electrode 122 and the gate insulating layer 124. In addition, the gate spacer 126 may be arranged on both sidewalls of the gate capping layer 128.

In some embodiments, the gate electrode 122 may include doped polysilicon, a metal, a conductive metal nitride, a conductive metal carbide, a conductive metal silicide, or a combination thereof. For example, the gate electrode 122 may include, but is not limited to, Al, Cu, Ti, Ta, W, Mo, TaN, NiSi, CoSi, TiN, WN, TiAl, TiAlN, TaCN, TaC, TaSiN, or a combination thereof. In an embodiment, the gate electrode 122 includes a work function metal-containing layer (not shown) and a gap-fill metal film (not shown). The work function metal-containing layer may include at least one metal selected from Ti, W, Ru, Nb, Mo, Hf, Ni, Co, Pt, Yb, Tb, Dy, Er, and Pd. The gap-fill metal film may include a W film or an Al film. In some embodiments, the gate electrode 122 may include, but is not limited to, a stacked structure of TiAlC/TiN/W, a stack structure of TiN/TaN/TiAlC/TiN/W, or a stacked structure of TiN/TaN/TiN/TiAlC/TiN/W.

In some embodiments, the gate insulating layer 124 may include a silicon oxide film, a silicon oxynitride film, a high-k film having a higher dielectric constant than a silicon oxide film, or a combination thereof. The high-k film may include a metal oxide or a metal oxynitride. For example, the high-k film, which may be used as the gate insulating layer 124, may include, but is not limited to, HfO₂, HfSiO, HfSiON, HfTaO, HfTiO, HfZrO, ZrO₂, Al₂O₃, or a combination thereof.

In some embodiments, the gate spacer 126 may include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof. In some embodiments, the gate capping layer 128 may include silicon nitride or silicon oxynitride.

A recess RS may be formed to extend to the inside of the fin-type active region FA on both sides of the gate structure GS, and the source/drain region SD may be formed in the recess RS. For example, a portion of the fin-type active region FA may be removed to form the recess RS. The source/drain region SD may be formed in the recess RS and may be connected to either end of each of the plurality of semiconductor patterns NS. In an embodiment, the source/drain region SD has an upper surface that is at a higher level than an upper surface of an uppermost semiconductor pattern NS. As shown in FIG. 5, the source/drain region SD may have a plurality of inclined sidewalls SD_S and may have a vertical cross-sectional shape of, for example, a hexagon, a pentagon, a rhombus, a corner-rounded polygon, or the like.

In some embodiments, the source/drain region SD may include, but is not limited to, a doped SiGe film, a doped Ge film, a doped SiC film, or a doped InGaAs film. The recess RS may be formed by partially removing a semiconductor pattern NS on either side of the gate structure GS, and a semiconductor layer may be grown by an epitaxy process to fill the inside of the recess RS, thereby forming the source/drain region SD. In an embodiment, the source/drain region SD includes a plurality of semiconductor layers having different compositions from each other. For example, the source/drain region SD may include a lower semiconductor layer (not shown), an upper semiconductor layer (not shown), and a capping semiconductor layer (not shown), which fill the recess RS in the stated order. For example, the lower semiconductor layer, the upper semiconductor layer, and the capping semiconductor layer may each include SiC and may respectively include each of Si and C in different amounts.

An inter-gate dielectric 132 may be formed between the gate structures GS to cover the source/drain region SD. For example, an upper surface of the inter-gate dielectric 132 may be at the same level as an upper surface of the gate structure GS. An upper insulating layer 134 may be arranged on the inter-gate dielectric 132 and the gate structure GS. The inter-gate dielectric 132 and the upper insulating layer 134 may each include silicon oxide or silicon oxynitride.

A gate cut insulating layer GCI may be arranged between two gate structures GS arranged adjacent to each other in the second horizontal direction (Y direction). The gate cut insulating layer GCI may have a bottom surface, which is at the same level as a bottom surface of the gate electrode 122, and an upper surface, which is at the same level as an upper surface of the upper insulating layer 134.

A first contact 140 may be arranged on the source/drain region SD. For example, the first contact 140 may include a contact plug 142 and a conductive barrier layer 144, which are arranged in a first contact hole 140H passing through the inter-gate dielectric 132 and the upper insulating layer 134. For example, the conductive barrier layer 144 may surround the contact plug 142. The contact plug 142 may include at least one of tungsten (W), cobalt (Co), molybdenum (Mo), nickel (Ni), ruthenium (Ru), copper (Cu), aluminum (Al), silicides thereof, and alloys thereof. The conductive barrier layer 144 may include at least one of ruthenium (Ru), titanium (Ti), titanium nitride (TiN), tantalum (Ta), tantalum nitride (TaN), tungsten (W), titanium silicon nitride (TiSiN), titanium silicide (TiSi), and tungsten silicide (WSi). Although not shown, a metal silicide layer may be further arranged between the first contact 140 and the source/drain region SD.

In an embodiment, the first contact 140 is arranged to cover at least a portion of an inclined surface SD_S of the source/drain region SD. For example, the first contact 140 may cover an inclined edge of the source/drain region SD. A bottom surface of the first contact 140 may be at a lower level than an uppermost surface SD_T of the source/drain region SD. Therefore, a relatively large contact area between the first contact 140 and the source/drain region SD may be secured. In an embodiment, the first contact 140 has a flat bottom surface such that the first contact 140 is arranged on the uppermost surface SD_T of the source/drain region SD without covering the inclined surface SD_S of the source/drain region SD. For example, in an embodiment, a bottom surface of the first contact 140 is entirely flat.

A second contact 150 may be arranged on the gate structure GS. The second contact 150 may include a contact plug 152 and a conductive barrier layer 154 surrounding a sidewall and a bottom surface of the contact plug 152. The second contact 150 may be arranged in a second contact hole 150H. In an embodiment, the contact hole 150H passes through the upper insulating layer 134 and the gate capping layer 128 and exposes the upper surface of the gate electrode 122.

A front wiring structure FWS may be arranged on the upper insulating layer 134. The front wiring structure FWS may include wiring layers (that is, a first wiring layer FML1 and a second wiring layer FML2) and vias (that is, a first via FV1 and a second via FV2), and an interlayer dielectric 162 may be arranged on the upper insulating layer 134 to cover the front wiring structure FWS. For example, the interlayer dielectric 162 may include a plurality of material layers, and the respective material layers may be arranged to cover upper surfaces and bottom surfaces of the wiring layers (that is, FML1 and FML2) and surround sidewalls of the vias (that is, FV1 and FV2). In some embodiments, the interlayer dielectric 162 may include an oxide film, a nitride film, an ultra-low-k (ULK) film having an ultra-low dielectric constant (that is, k) of about 2.2 to about 2.4, or a combination thereof.

In some embodiments, as shown in FIGS. 3 to 5, the first via FV1 is arranged on an upper surface of the second contact 150, and the first wiring layer FML1 is arranged on an upper surface of the first via FV1. In addition, the second via FV2 may be arranged on an upper surface of the first wiring layer FML1, and the second wiring layer FML2 may be arranged on an upper surface of the second via FV2. For example, the first wiring layer FML1 may extend in the first horizontal direction (X direction), and the second wiring layer FML2 may extend in the second horizontal direction (Y direction). However, unlike the example shown in FIG. 3, the wiring layers (that is, FML1 and FML2) may include three or more wiring layers, and an extension direction of each of the wiring layers (that is, FML1 and FML2) is not limited to the examples shown in FIGS. 3 to 5.

A backside wiring structure BWS may be arranged on the second surface 110B of the substrate 110. The backside wiring structure BWS may include a power delivery network for applying a power supply voltage and a ground voltage to the transistor TR1 in each of the plurality of cells CR. For example, the power delivery network may supply first and second voltages, where the first voltage is higher than the second voltage. In some embodiments, the backside wiring structure BWS may include a main power rail MPR disposed on the second surface 110B of the substrate 110, backside wiring layers (that is, a first backside wiring layer BML1 and a second backside wiring layer BML2), and backside vias (that is, a first backside via BV1 and a second backside via BV2).

In an embodiment, the main power rail MPR is arranged on the second surface 110B of the substrate 110. The main power rail MPR may be in direct contact with the second surface 110B of the substrate 110 or may be arranged adjacent to the second surface 110B of the substrate 110 with a passivation layer between the main power rail MPR and the second surface 110B of the substrate 110. The main power rail MPR may have a relatively large width and extend in the first horizontal direction (X direction). The first backside wiring layer BML1 may be arranged at a first vertical level that is different from a vertical level of the main power rail MPR. For example, the first backside wiring layer BML1 may be arranged at the first vertical level that is farther from the second surface 110B of the substrate 110 than the vertical level of the main power rail MPR. The second backside wiring layer BML2 may be arranged at a second vertical level that is farther from the second surface 110B of the substrate 110 than the first vertical level. The first backside via BV1 may be arranged between the main power rail MPR and the first backside wiring layer BML1 and may make an electrical connection therebetween. The second backside via BV2 may be arranged between the first backside wiring layer BML1 and the second backside wiring layer BML2 and may make an electrical connection therebetween. A backside interlayer dielectric 164 may be arranged on the second surface 110B of the substrate 110 to cover the backside wiring structure BWS.

In an embodiment, the main power rail MPR is electrically connected to the first contact 140 by a backside buried wiring layer BPR, which passes through the substrate 110, and a power via VPR disposed on the first surface 110F of the substrate 110.

The backside buried wiring layer BPR may be buried in the substrate 110 and may extend from the first surface 110F to the second surface 110B of the substrate 110. In an embodiment, the backside buried wiring layer BPR is arranged in a buried trench BT, which passes through the substrate 110 from the first surface 110F to the second surface 110B of the substrate 110. For example, the buried trench BT may be formed using the same process as a process of forming the device isolation trench 112T from the first surface 110F of the substrate 110 or in a process subsequent to the process of forming the device isolation trench 112T.

In some embodiments, the backside buried wiring layer BPR may have an inclined sidewall. For example, the backside buried wiring layer BPR may have an inclined sidewall such that a first width W1 thereof at a first vertical level LV1 equal to that of the first surface 110F of the substrate 110 is greater than a second width W2 thereof at a second vertical level LV2 equal to that of the second surface 110B of the substrate 110.

In some embodiments, the insulating liner 112L may be arranged in the buried trench BT and may continuously extend from a sidewall of the fin-type active region FA to an inner wall of the buried trench BT. Therefore, a portion of the insulating liner 112L, which is arranged on an upper portion of the sidewall of the fin-type active region FA, may be in contact with the buried insulating layer 112F, and a portion of the insulating liner 112L, which is arranged on a lower portion of the sidewall of the fin-type active region FA (for example, on the inner wall of the buried trench BT), may be in contact with the backside buried wiring layer BPR. In some embodiments, an additional insulating liner may be further arranged between the insulating liner 112L and the backside buried wiring layer BPR.

In some embodiments, in a plan view, the backside buried wiring layer BPR may be arranged between two adjacent fin-type active regions FA in the second horizontal direction (Y direction). For example, the backside buried wiring layer BPR may be arranged between two adjacent source/drain regions SD in the second horizontal direction (Y direction). In addition, the backside buried wiring layer BPR may be arranged between two adjacent fin-type active regions FA in the second horizontal direction (Y direction) to vertically overlap the device isolation film 112. For example, an upper surface of the backside buried wiring layer BPR may be in contact with a bottom surface of the buried insulating layer 112F.

In some embodiments, the backside buried wiring layer BPR may include a wiring metal layer 172F and a conductive barrier layer 172B. The wiring metal layer 172F may include at least one of tungsten (W), cobalt (Co), molybdenum (Mo), nickel (Ni), ruthenium (Ru), copper (Cu), aluminum (Al), silicides thereof, and alloys thereof. The conductive barrier layer 172B may include at least one of ruthenium (Ru), titanium (Ti), titanium nitride (TiN), tantalum (Ta), tantalum nitride (TaN), tungsten (W), titanium silicon nitride (TiSiN), titanium silicide (TiSi), and tungsten silicide (WSi).

The conductive barrier layer 172B may be arranged to cover a lateral surface and an upper surface of the wiring metal layer 172F. For example, the conductive barrier layer 172B may be arranged on the sidewall of the buried trench BT and between the upper surface of the wiring metal layer 172F and the bottom surface of the buried insulating layer 112F.

The power via VPR may pass through the device isolation film 112 and the inter-gate dielectric 132 and extend in the vertical direction (Z direction). For example, the power via VPR may penetrate the device isolation film 112 and the inter-gate dielectric 132. The power via VPR may be arranged between the bottom surface of the first contact 140 and the upper surface of the backside buried wiring layer BPR, as shown in FIG. 5, and may electrically connect the first contact 140 and the backside buried wiring layer BPR to each other. For example, the power via VPR may be arranged in a power via hole VT and may include a via metal layer 174F and a conductive barrier layer 174B. In an embodiment, as shown in FIG. 5, an upper surface of the power via VPR is covered by the bottom surface of the first contact 140, and the conductive barrier layer 144 is arranged between the upper surface of the power via VPR and the contact plug 142 of the first contact 140.

In an embodiment, the power via VPR and the first contact 140 are integrally formed. For example, the conductive barrier layer 174B and the conductive barrier layer 144 of the first contact 140 may form a continuous material layer including the same material, and the via metal layer 174F and the contact plug 142 may form a continuous material layer including the same material. For example, a single first layer may be used to form the conductive barrier layer 174B and the conductive barrier layer 144 and single second layer may be used to form the via metal layer 174F and the contact plug 142.

In an embodiment, the power via VPR has an inclined sidewall such that the width of the upper surface of the power via VPR is greater than the width of the bottom surface of the power via VPR. In an embodiment, the width of a bottom surface of the power via VPR, which is in contact with the upper surface of the backside buried wiring layer BPR, is less than the width of the upper surface of the power via VPR, which is in contact with the bottom surface of the first contact 140.

An etching process may be performed to remove a portion of the substrate 110 from the second surface 110B of the substrate 110 to form a power wiring structure electrically connected to a device on the first surface 110F of the substrate 110. However, a misalignment of the substrate 110 or a mask pattern is prone to occur in the etching process. Thus, a manufacturing process difficulty may be increased, or there is a need to form a trench having a limited width. While a through-via may be formed to extend from the first surface 110F of the substrate 110 to the second surface 110B of the substrate 110, the manufacturing process difficulty may be increased when the aspect ratio of the through-via is too high.

On the other hand, according to an embodiment of the disclosure, the buried trench BT is formed using the same process as the process of forming the device isolation trench 112T from the first surface 110F of the substrate 110 or in the process subsequent to the process of forming the device isolation trench 112T, followed by forming a sacrificial buried layer 180 in a lower portion of the buried trench BT, and then, the transistor TR1 is formed. Next, the sacrificial buried layer 180 may be exposed by grinding the substrate 110 from the second surface 110B of the substrate 110, followed by removing the sacrificial buried layer 180, and then, the backside buried wiring layer BPR may be formed in the buried trench BT. Therefore, because there is no need to perform a patterning process on the second surface 110B of the substrate 110, the generation of defects due to a mask pattern misalignment may be prevented. In addition, because the backside buried wiring layer BPR may be formed with a relatively large width between two adjacent fin-type active regions FA, the resistance of a wiring line from the backside wiring structure BWS to the transistor TR1 may be reduced. Therefore, the integrated circuit device 100 may have excellent electrical performance.

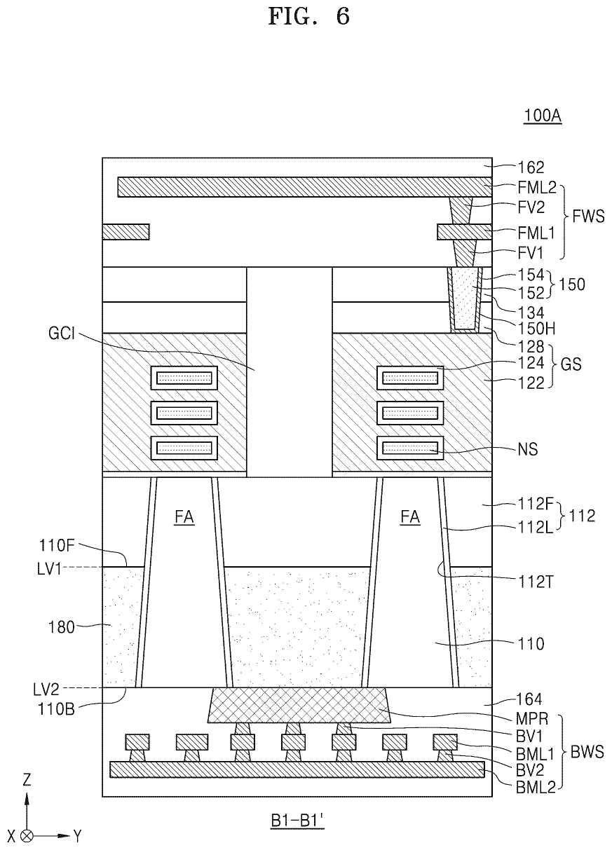

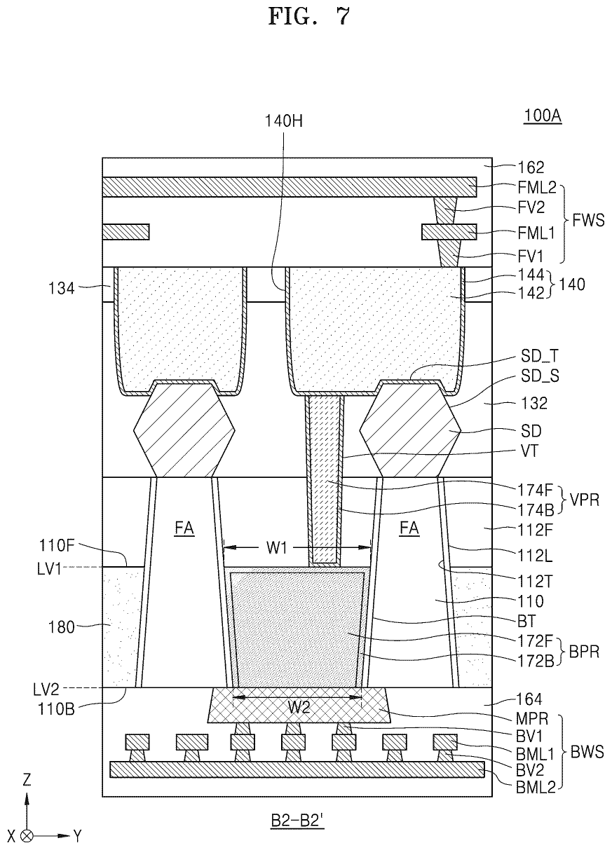

FIGS. 6 and 7 are cross-sectional views of an integrated circuit device 100A according to an embodiment. Specifically, FIG. 6 is a cross-sectional view corresponding to a cross-section taken along the line B1-B1′ of FIG. 2, and FIG. 7 is a cross-sectional view corresponding to a cross-section taken along the line B2-B2′ of FIG. 2. In FIGS. 6 and 7, the same reference numerals as in FIGS. 1 to 5 respectively denote the same components.

Referring to FIGS. 6 and 7, a lower portion of a sidewall of the fin-type active region FA may be covered by the sacrificial buried layer 180, and the upper portion of the sidewall of the fin-type active region FA may be covered by the device isolation film 112. For example, an upper surface of the sacrificial buried layer 180 may be at the first vertical level LV1, and a bottom surface of the sacrificial buried layer 180 may be at the second vertical level LV2. In an embodiment, the first vertical level LV1 is higher than the second vertical level LV2.

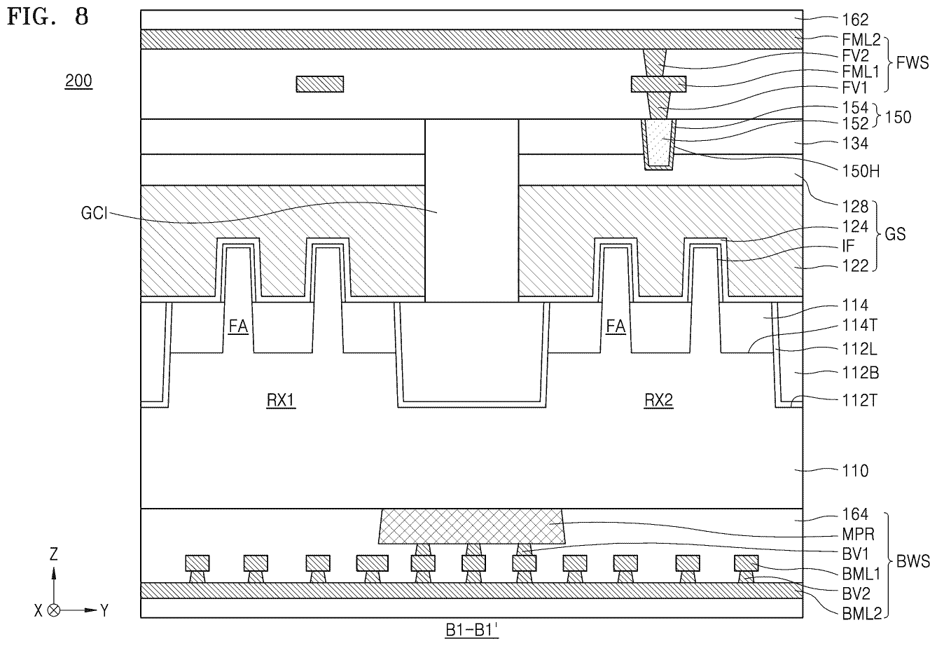

FIG. 8 is a cross-sectional view illustrating an integrated circuit device 200 according to an embodiment.

Referring to FIG. 8, the integrated circuit device 200 may include a FinFET transistor. For example, the plurality of fin-type active regions FA may be arranged on the first active area RX1 and the second active area RX2 to protrude in the vertical direction (Z direction) from the first surface 110F of the substrate 110. A shallow device isolation film 114 may be arranged in a shallow device isolation trench 114T on either side of the fin-type active region FA. For example, portions of the shallow device isolation film 114 may contact respective sides of a fin-type active region FA. In addition, the device isolation trench 112T may be arranged outside the first active area RX1 and the second active area RX2 and between the first active area RX1 and the second active area RX2, and the device isolation film 112 may be arranged in the device isolation trench 112T. The gate structure GS may further include an interface layer IF between the gate insulating layer 124 and the fin-type active region FA. The interface layer IF may include silicon oxide or be formed entirely of silicon oxide.

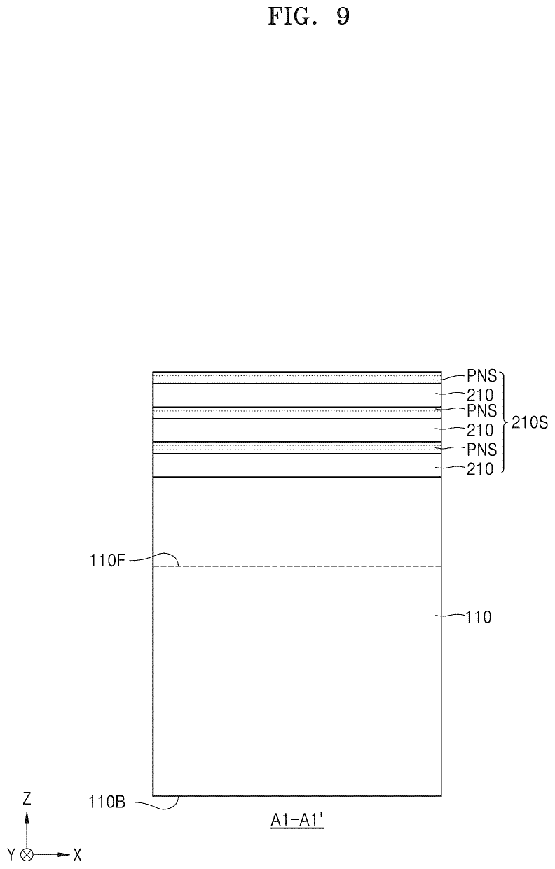

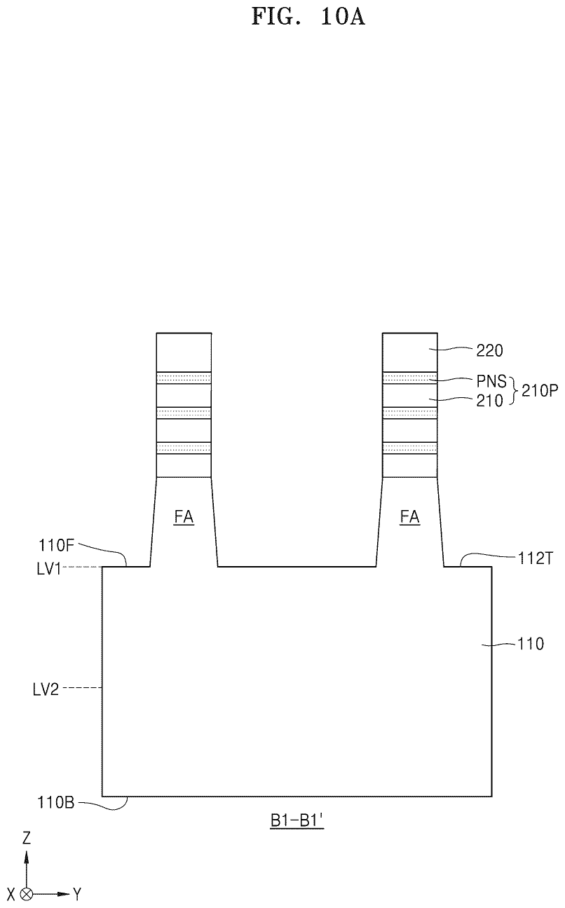

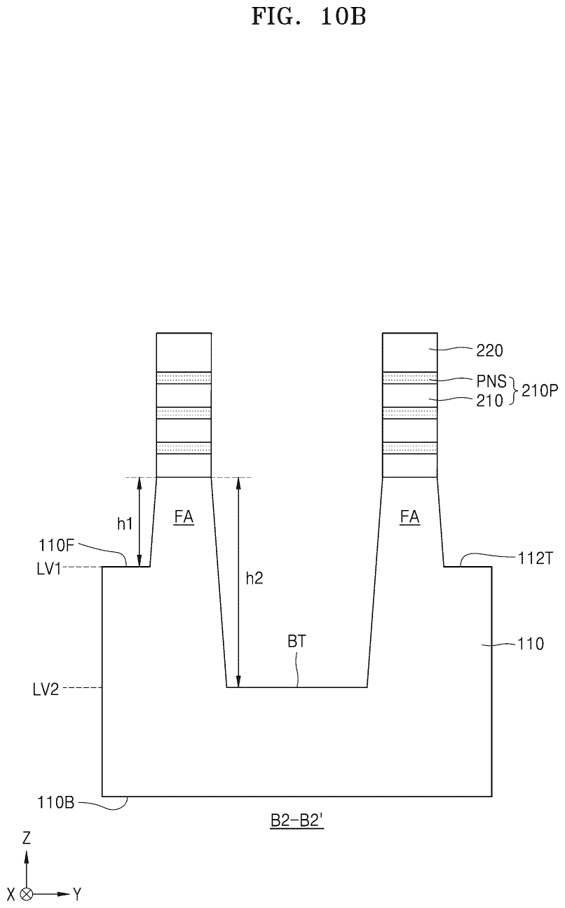

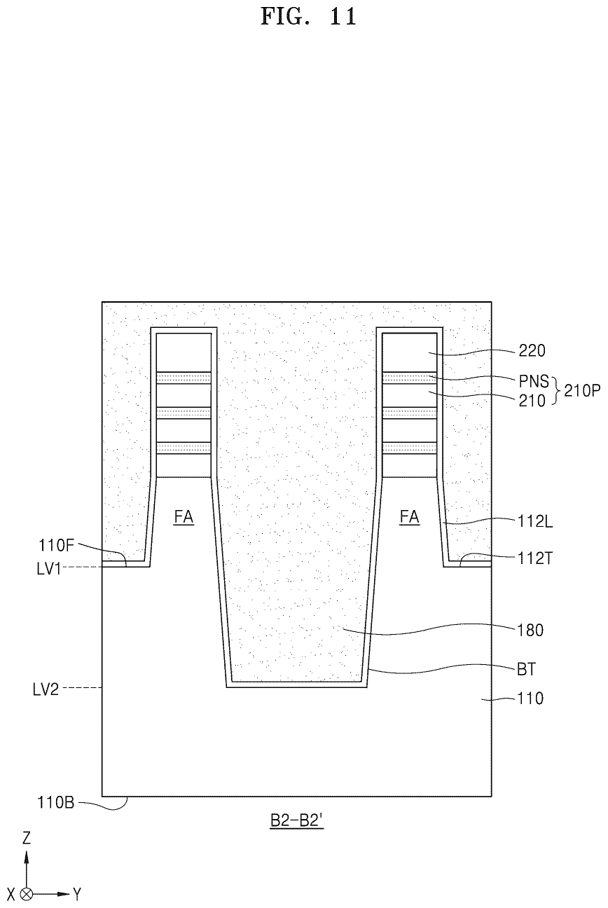

FIGS. 9 to 20 are cross-sectional views illustrating a method of manufacturing the integrated circuit device 100, according to an embodiment. Specifically, FIGS. 9, 14A, 15A, and 16A are cross-sectional views each corresponding to a cross-section taken along the line A1-A1′ of FIG. 2, FIGS. 10A, 14B, 15B, 16B, and 17A are cross-sectional views each corresponding to a cross-section taken along the line B1-B1′ of FIG. 2, and FIGS. 10B, 11, 12, 13, 15C, 17B, 18, 19, and 20 are cross-sectional views each corresponding to a cross-section taken along the line B2-B2′ of FIG. 2.

Referring to FIG. 9, a sacrificial layer 210 and a channel semiconductor layer PNS may be alternately formed in the stated order on the first surface 110F of the substrate 110, thereby forming a preliminary channel stack 210S. The sacrificial layer 210 and the channel semiconductor layer PNS may each be formed by an epitaxy process. For example, a sacrificial layer 210 may be formed on the substrate 110, the channel semiconductor layer PNS (e.g., a channel layer) may be formed on the sacrificial layer 210, and the process may repeated until several alternating layers are formed.

In an embodiment, the sacrificial layer 210 and the channel semiconductor layer PNS are respectively formed of materials having etch selectivities with respect to each other. For example, each of the sacrificial layer 210 and the channel semiconductor layer PNS may include a single crystal layer of a Group IV semiconductor, a Group IV-VI compound semiconductor, or a Group III-V compound semiconductor, and the sacrificial layer 210 and the channel semiconductor layer PNS may include different materials from each other. In an example, the sacrificial layer 210 may include SiGe, and the channel semiconductor layer PNS may include single-crystal silicon.

In some embodiments, the epitaxy process may include a chemical vapor deposition (CVD) process, such as vapor-phase epitaxy (VPE) or ultra-high vacuum chemical vapor deposition (UHV-CVD), a molecular beam epitaxy process, or a combination thereof. In the epitaxy process, a liquid-phase or gas-phase precursor may be used as a precursor to form each of the sacrificial layer 210 and the channel semiconductor layer PNS.

Referring to FIGS. 10A and 10B, a hardmask pattern 220 may be formed on the channel semiconductor layer PNS to extend with a certain length in the first horizontal direction (X direction). For example, the hardmask pattern 220 may be formed on the upper most channel semiconductor layer PNS that is exposed. The sacrificial layer 210, the channel semiconductor layer PNS, and the substrate 110 may then be etched by using the hardmask pattern 220 as an etch mask, thereby forming a preliminary channel pattern 210P and the device isolation trench 112T. Next, a portion of the substrate 110, which is exposed at the bottom of the device isolation trench 112T, may be further etched, thereby forming the buried trench BT. The device isolation trench 112T has a first depth h1, and the buried trench BT has a second depth h2. In an embodiment a value of the second depth h2 corresponds to about 150% to about 500% of the first depth h1. Here, the bottom surface of the device isolation trench 112T may be defined to be at the first vertical level LV1, and the bottom surface of the buried trench BT may be defined to be at the second vertical level LV2.

In an embodiment, as shown in FIG. 10B, one sidewall of the fin-type active region FA may be exposed by the device isolation trench 112T, and the other sidewall of the fin-type active region FA may be exposed by the buried trench BT. For example, an etching process for forming the buried trench BT may be performed directly after an etching process for forming the device isolation trench 112T. In an embodiment, the device isolation trench 112T and the buried trench BT respectively have sidewalls inclined at similar tilt angles.

Referring to FIG. 11, the insulating liner 112L is formed on the inner wall of the device isolation trench 112T and the inner wall of the buried trench BT, and the sacrificial buried layer 180 is formed on the insulating liner 112L. The sacrificial buried layer 180 may be formed on the insulating liner 112L to have a sufficiently high thickness to completely fill the insides of the device isolation trench 112T and the buried trench BT. In some embodiments, the sacrificial buried layer 180 may include silicon nitride, silicon oxynitride, or a dielectric material. In an embodiment, the sacrificial buried layer 180 includes a material having etch selectivity with respect to the insulating liner 112L.

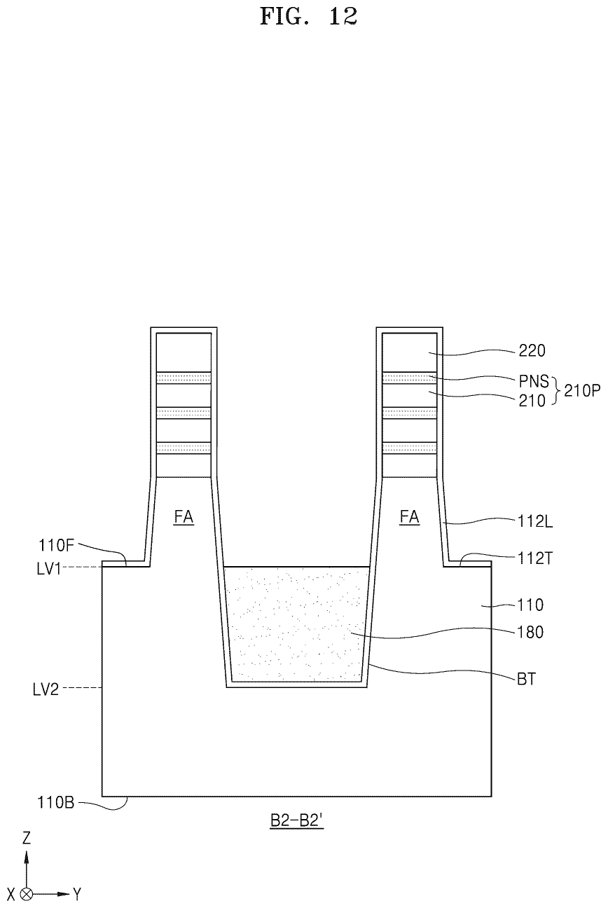

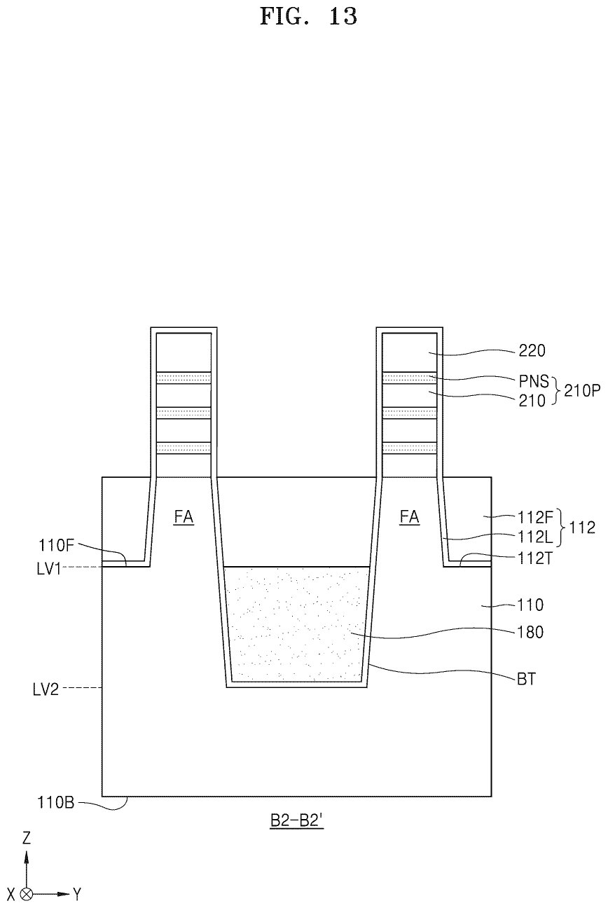

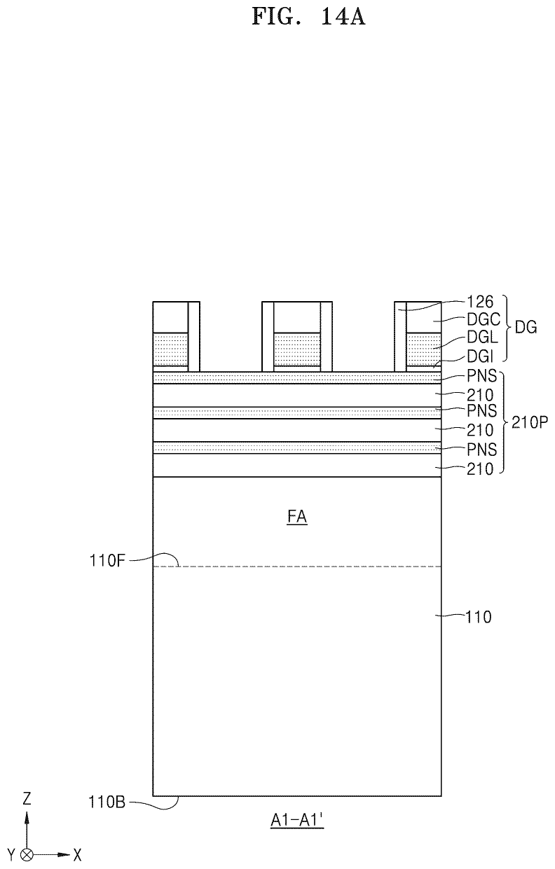

Referring to FIG. 12, a portion of the sacrificial buried layer 180, which is arranged in the device isolation trench 112T, may be removed, and the sacrificial buried layer 180 may remain in a lower portion of the buried trench BT. For example, the portion of the sacrificial buried layer 180 adjacent to the sacrificial layers 210, the channel semiconductor layers PNS, and the hardmask pattern 220 may be removed. The process of removing the sacrificial buried layer 180 may include an etch-back process or a recess process, and the insulating liner 112L may remain without being removed in the etch-back process or the recess process. In an embodiment, the sacrificial buried layer 180 remaining in the lower portion of the buried trench BT has an upper surface that is at a level that is equal to or lower than a level of the bottom of the device isolation trench 112T. For example, the upper surface of the sacrificial buried layer 180 remaining in the lower portion of the buried trench BT may be at the first vertical level LV1.

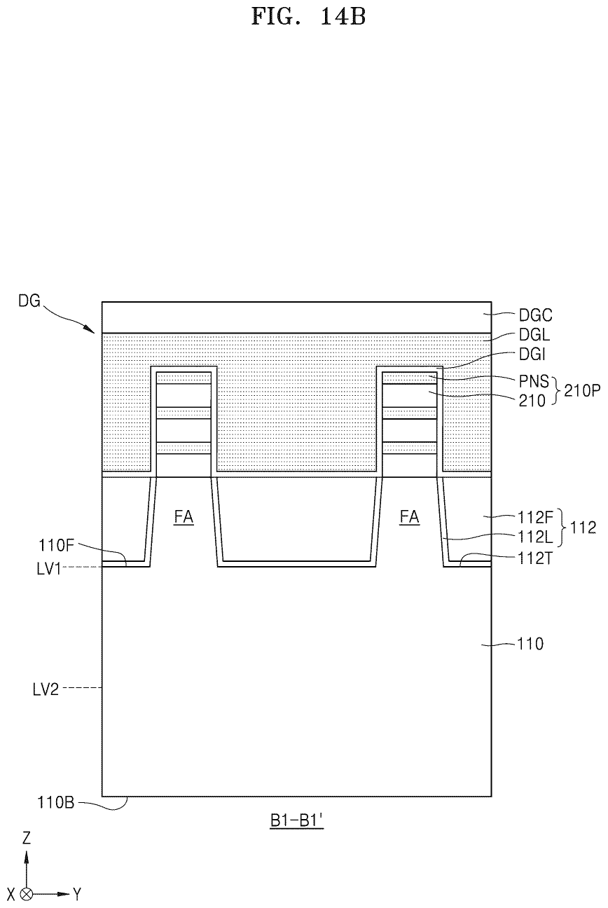

Referring to FIG. 13, the inside of the device isolation trench 112T may be filled with an insulating material, followed by planarizing an upper portion of the insulating material, thereby forming the buried insulating layer 112F to fill the device isolation trench 112T. The insulating liner 112L and the buried insulating layer 112F may be collectively referred to as the device isolation film 112. For example, the planarizing may include performing a process that results in the device isolation film 112 having a flat or substantially flat upper surface.

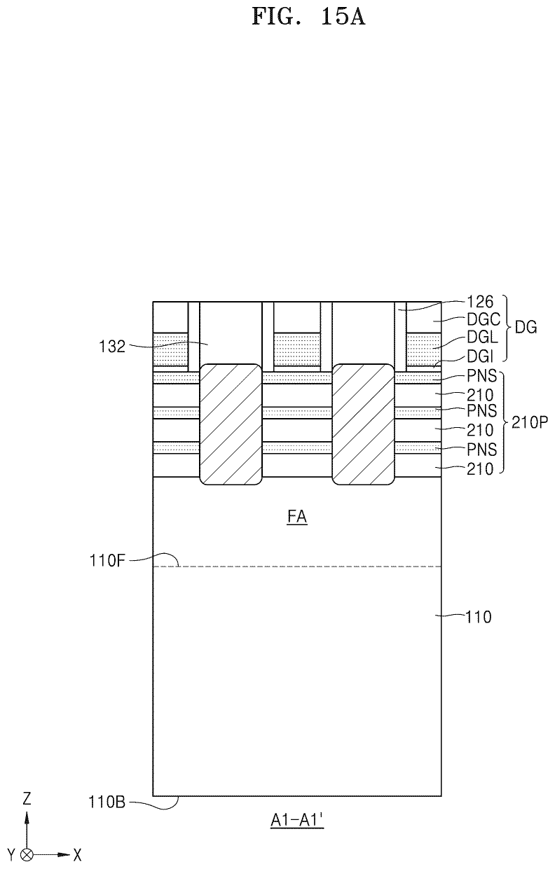

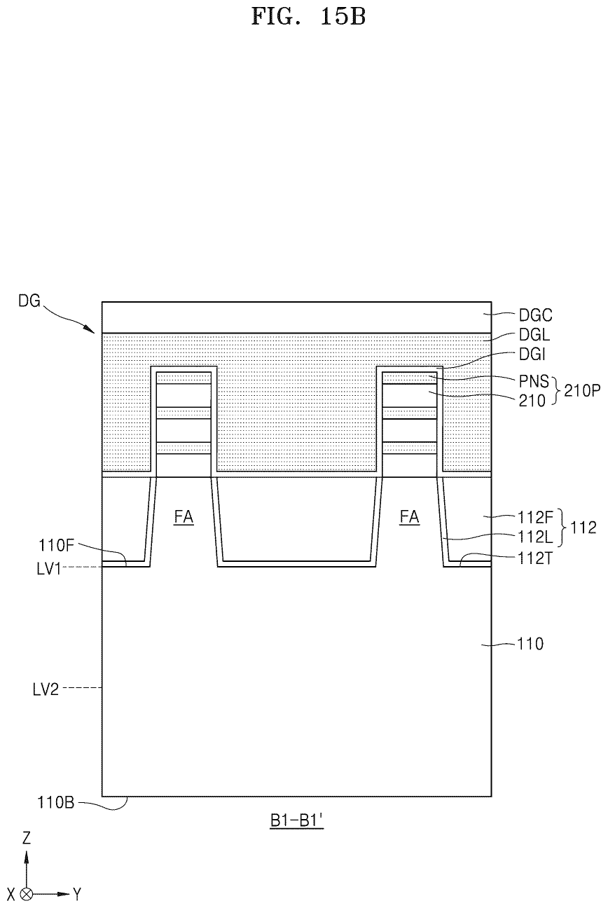

Referring to FIGS. 14A and 14B, a dummy gate structure DG may be formed on the preliminary channel pattern 210P and the device isolation film 112. Each dummy gate structure DG may include a dummy gate insulating layer DGI, a dummy gate line DGL, a dummy gate capping layer DGC, and a spacer 126. For example, the dummy gate line DGL may be formed on the dummy gate insulating layer DGI, and the dummy gate capping layer DGC may be formed on the dummy gate line DGL.

For example, the dummy gate line DGL may be formed of polysilicon, and the dummy gate capping layer DGC may be formed of a silicon nitride film. The dummy gate insulating layer DGI may be formed of a material having etch selectivity with respect to the dummy gate line DGL, for example, at least one film selected from thermal oxide, silicon oxide, and silicon nitride. The spacer 126 may be formed of silicon nitride. In an embodiment, the dummy gate capping layer DGC entirely includes silicon nitride film and the spacer entirely includes silicon nitride.

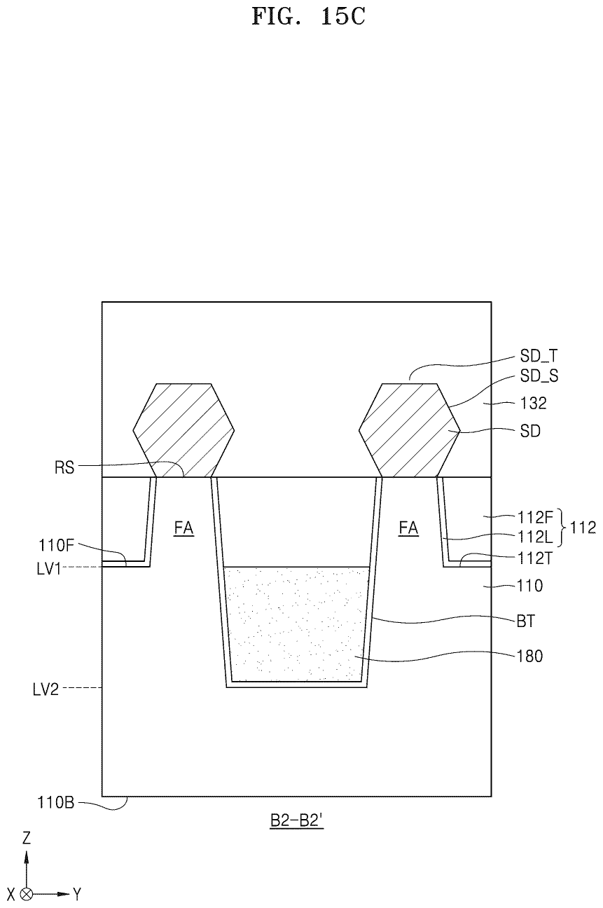

Referring to FIGS. 15A to 15C, the recess RS is formed on both sides of the dummy gate structure DG by partially etching the preliminary channel pattern 210P and the substrate 110 on both sides of the dummy gate structure DG. As the recess RS is formed, the preliminary channel pattern 210P may be separated into the plurality of semiconductor patterns NS.

Next, the source/drain region SD may be formed in the recess RS. For example, the source/drain region SD may be formed by epitaxially growing a semiconductor material on respective surfaces of the substrate 110, the sacrificial layer 210, and the plurality of semiconductor patterns NS, which are exposed at an inner wall of the recess RS. The source/drain region SD may include at least one of an epitaxially grown Si layer, an epitaxially grown SiC layer, an epitaxially grown SiGe layer, and an epitaxially grown SiP layer.

Next, the inter-gate dielectric 132 may be formed on the source/drain region SD and a sidewall of the spacer 126. By planarizing upper portions of the dummy gate structure DG and the inter-gate dielectric 132, the dummy gate capping layer DGC of the dummy gate structure DG may be removed, and an upper surface of the dummy gate line DGL may be exposed.

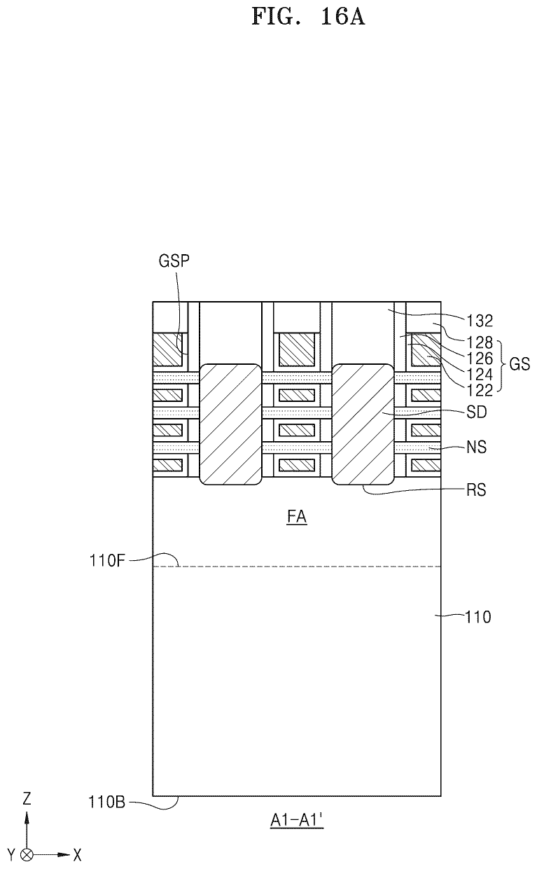

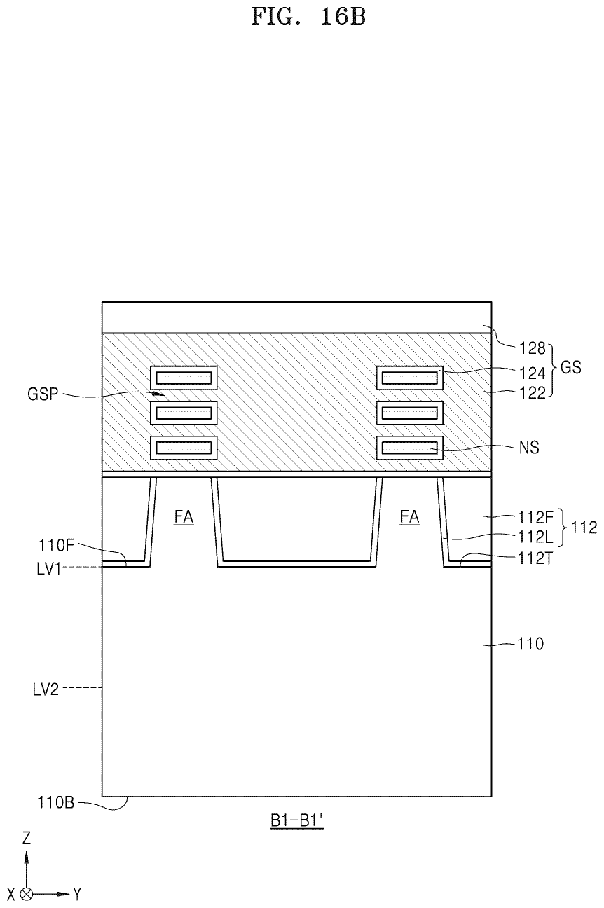

Referring to FIGS. 16A and 16B, a gate space GSP (e.g., a gate space layer) may be formed by removing the dummy gate line DGL and the dummy gate insulating layer DGI, which are exposed by the inter-gate dielectric 132.

Next, a plurality of sacrificial layers 210 remaining on the fin-type active region FA may be removed through the gate space GSP, thereby partially exposing the plurality of semiconductor patterns NS and the upper surface of the fin-type active region FA. The gate space GSP may be expanded or extended to a space between the plurality of semiconductor patterns NS and a space between a lowermost semiconductor pattern NS and the fin-type active region FA. The process of removing the plurality of sacrificial layers 210 may include a wet etching process using a difference in etch selectivity between the sacrificial layer 210 and the plurality of semiconductor patterns NS.

Next, the gate insulating layer 124 may be formed on surfaces exposed by the gate space GSP. Next, the gate electrode 122 may be formed on the gate insulating layer 124 to fill the gate space GSP. For example, a work function metal-containing layer (not shown) may be conformally formed on an inner wall of the gate space GSP, and then, a gap-fill metal film (not shown) may be formed on the work function metal-containing layer to fill the gate space GSP. Next, an upper portion of the gap-fill metal film may be planarized such that an upper surface of the inter-gate dielectric 132 is exposed, thereby forming the gate electrode 122.

In some embodiments, the work function metal-containing layer may be formed of Al, Cu, Ti, Ta, W, Mo, TaN, NiSi, CoSi, TiN, WN, TiAl, TiAlC, TiAlN, TaCN, TaC, TaSiN, or a combination thereof. The gap-fill metal film may be formed of Al, Cu, Ti, Ta, W, Mo, TaN, NiSi, CoSi, TiN, WN, TiAl, TiAlC, TiAlN, TaCN, TaC, TaSiN, or a combination thereof.

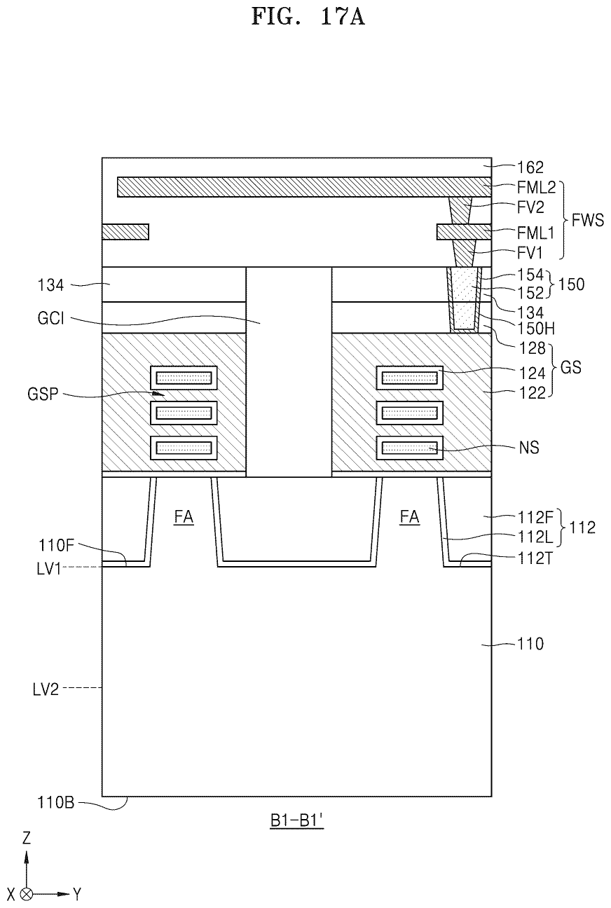

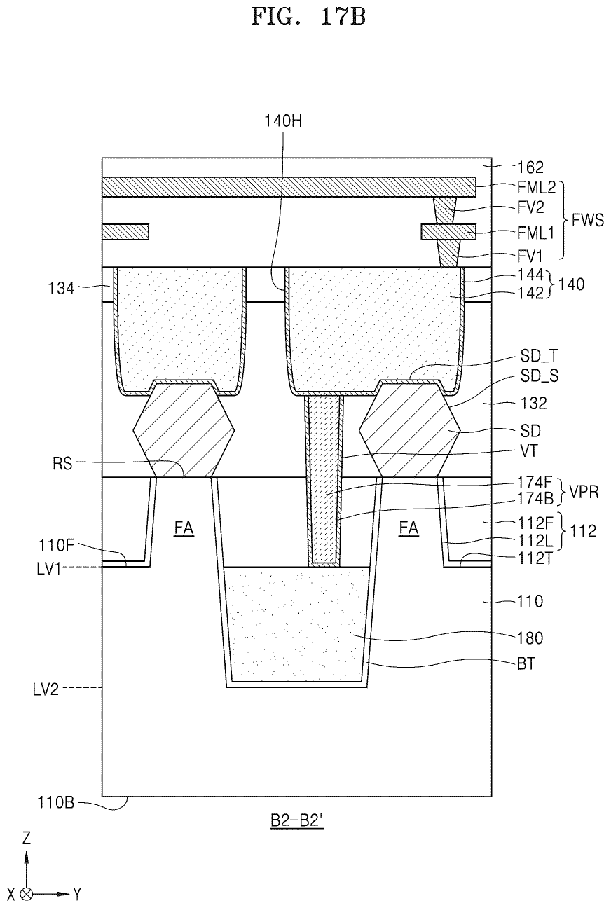

Referring to FIGS. 17A and 17B, the upper insulating layer 134 is formed on the gate electrode 122 and the inter-gate dielectric 132. Next, a mask pattern (not shown) may be formed on the upper insulating layer 134, followed by removing portions of the inter-gate dielectric 132 and the upper insulating layer 134 by using the mask pattern as an etch mask, thereby forming the power via hole VT to expose the upper surface of the sacrificial buried layer 180. Next, the conductive barrier layer 174B and the via metal layer 174F may be formed in the stated order on an inner wall of the power via hole VT.

Next, a mask pattern (not shown) may be formed on the upper insulating layer 134. Then, portions of the upper insulating layer 134 and the inter-gate dielectric 132 may be removed by using the mask pattern as an etch mask, thereby forming the first contact hole 140H. The conductive barrier layer 144 and the contact plug 142 may be formed in the stated order in the first contact hole 140H, thereby forming the first contact 140.

Next, the second contact hole 150H may be formed by removing portions of the upper insulating layer 134 and the gate capping layer 128. Then, the conductive barrier layer 154 and the contact plug 152 may be formed in the stated order in the second contact hole 150H, thereby forming the second contact 150.

The front wiring structure FWS, which includes the wiring layers (that is, FML1 and FML2) and the vias (that is, FV1 and FV2), and the interlayer dielectric 162, which surrounds the front wiring structure FWS, may be formed on the upper insulating layer 134.

Referring to FIG. 18, the height of the substrate 110 in the vertical direction (Z direction) may be reduced by removing a portion of the substrate 110 from the second surface 110B of the substrate 110. Here, the bottom of the buried trench BT and the bottom surface of the sacrificial buried layer 180 may be exposed. For example, the removing may result in the exposure of the bottom surface of the sacrificial buried layer 180.

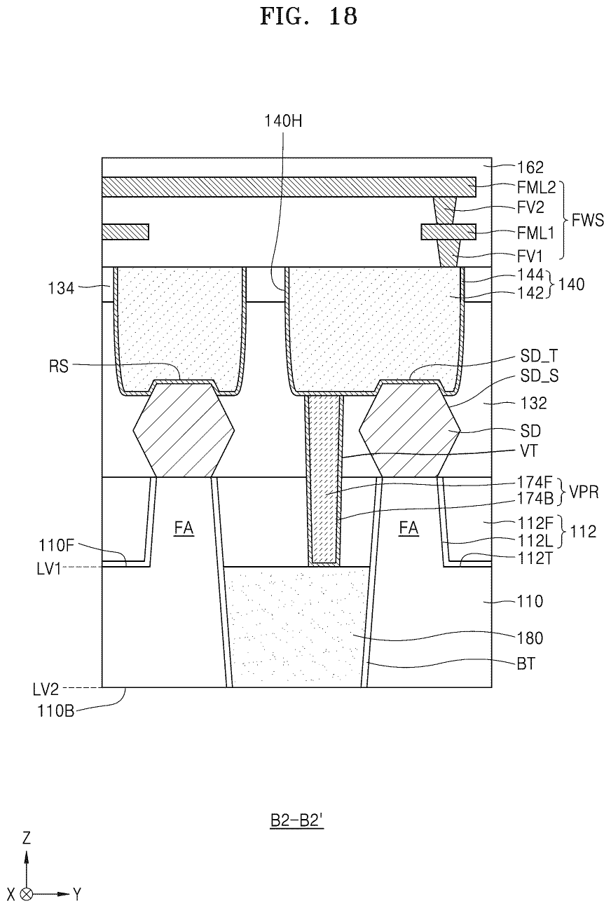

Referring to FIG. 19, the sacrificial buried layer 180 exposed at the second surface 110B of the substrate 110 may be removed. After the sacrificial buried layer 180 is removed, the bottom surface of the buried insulating layer 112F and the bottom surface of the power via VPR may be exposed. In an embodiment, the process of removing the sacrificial buried layer 180 includes a wet etching process using an aqueous solution of phosphoric acid as an etchant.

In the process of removing the sacrificial buried layer 180, a portion of the insulating liner 112L may remain on the inner wall of the buried trench BT without being removed.

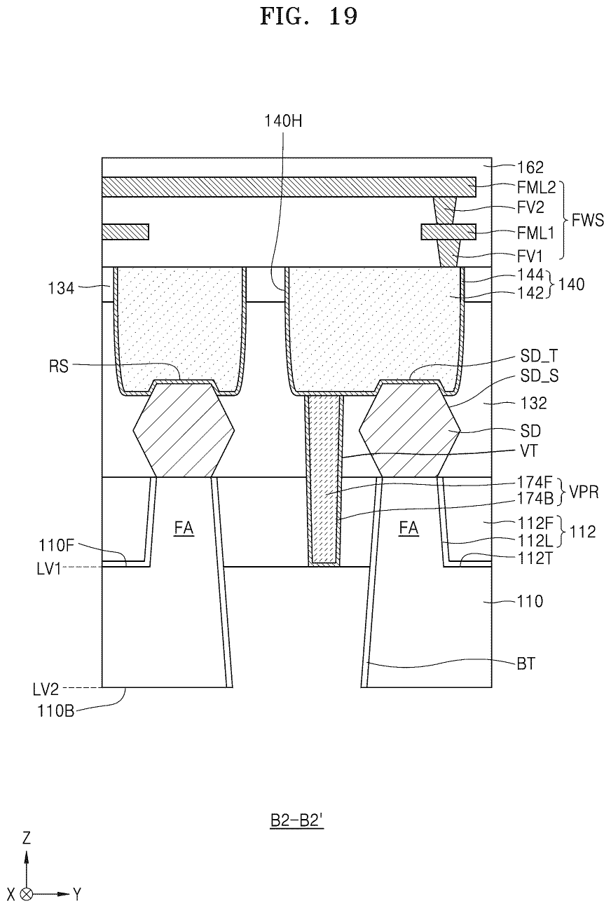

Referring to FIG. 20, the backside buried wiring layer BPR may be formed in the buried trench BT. In an embodiment, the backside buried wiring layer BPR includes the wiring metal layer 172F and the conductive barrier layer 172B. The conductive barrier layer 172B may be arranged to cover the lateral surface and the upper surface of the wiring metal layer 172F. For example, the conductive barrier layer 172B may be arranged on the sidewall of the buried trench BT and between the upper surface of the wiring metal layer 172F and the bottom surface of the buried insulating layer 112F.

Referring again to FIGS. 3 to 5, the backside wiring structure BWS and the backside interlayer dielectric 164 may be formed on the second surface 110B of the substrate 110. The backside wiring structure BWS may include the main power rail MPR, the backside wiring layers (that is, BML1 and BML2), and the backside vias (that is, BV1 and BV2), which are arranged on the second surface 110B of the substrate 110.

The integrated circuit device 100 may be formed by the processes described above. According to the manufacturing process according to some embodiments, the buried trench BT is formed using the same process as the process of forming the device isolation trench 112T from the first surface 110F of the substrate 110 or in the process subsequent to the process of forming the device isolation trench 112T, followed by forming the sacrificial buried layer 180 in the lower portion of the buried trench BT, and then, the transistor TR1 is formed. Next, the sacrificial buried layer 180 may be exposed by grinding the substrate 110 from the second surface 110B of the substrate 110, followed by removing the sacrificial buried layer 180, and then, the backside buried wiring layer BPR may be formed in the buried trench BT. Therefore, because there is no need to perform a patterning process on the second surface 110B of the substrate 110, the generation of defects due to a mask pattern misalignment may be prevented. In addition, because the backside buried wiring layer BPR may be formed with a relatively large width between two adjacent fin-type active regions FA, the resistance of a wiring line from the backside wiring structure BWS to the transistor TR1 may be reduced. Therefore, the integrated circuit device 100 may have excellent electrical performance.

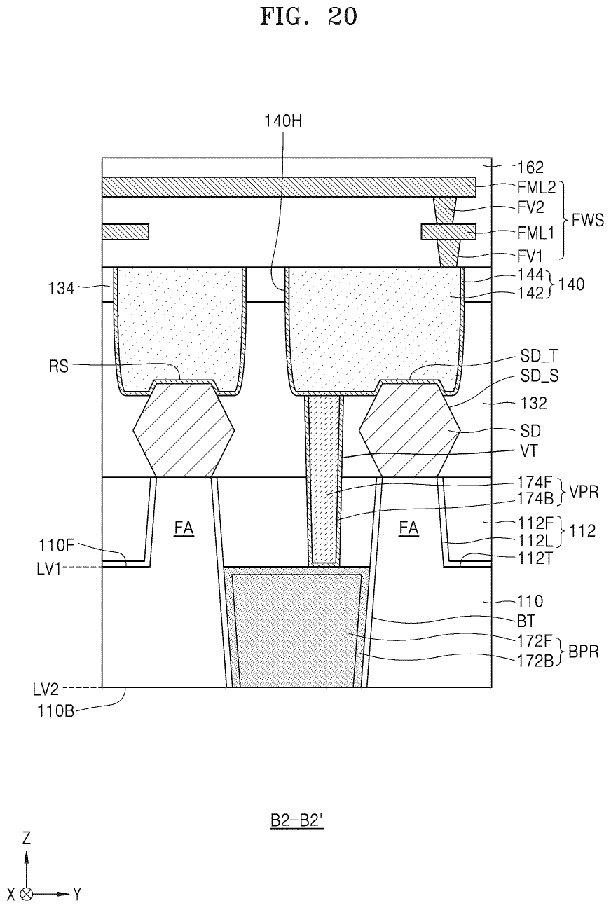

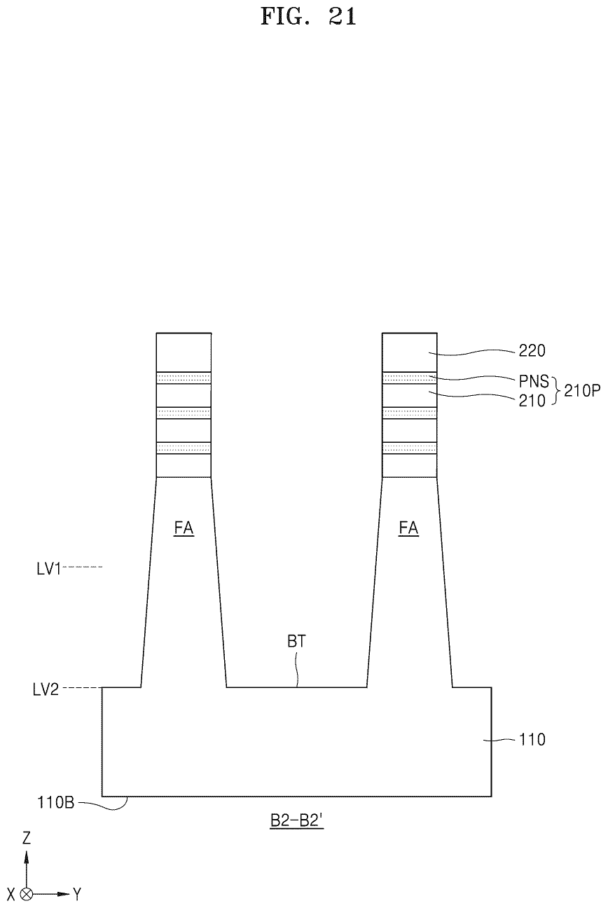

FIGS. 21 to 24 are cross-sectional views illustrating a method of manufacturing the integrated circuit device 100A, according to an embodiments. Specifically, FIGS. 21 to 24 are cross-sectional views each corresponding to a cross-section taken along the line B2-B2′ of FIG. 2.

Referring to FIG. 21, the hardmask pattern 220 may be formed on the channel semiconductor layer PNS to extend with a certain length in the first horizontal direction (X direction). Then, an etching of the sacrificial layer 210, the channel semiconductor layer PNS, and the substrate 110 may be performed by using the hardmask pattern 220 as an etch mask, thereby forming the preliminary channel pattern 210P and the buried trench BT. Both sidewalls of the fin-type active region FA may be exposed by the buried trench BT. The depth of the fin-type active region FA may be greater than that in the example described with reference to FIG. 10B.

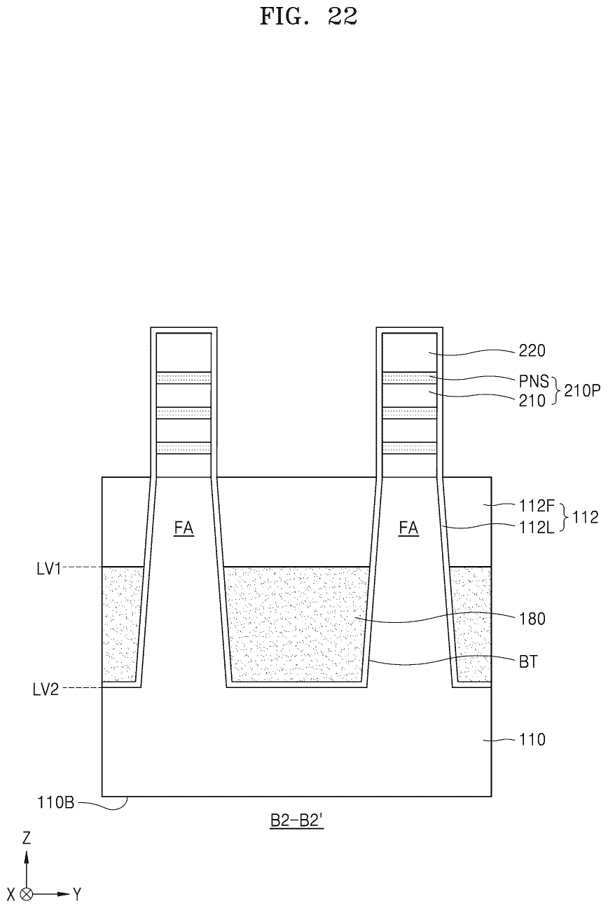

Referring to FIG. 22, the insulating liner 112L is formed on the inner wall of the buried trench BT, and the sacrificial buried layer 180 is formed on the insulating liner 112L. Next, by removing an upper portion of the sacrificial buried layer 180 by an etch-back process or a recess process, the sacrificial buried layer 180 may remain in the lower portion of the buried trench BT. Next, the upper portion of the buried trench BT may be filled with an insulating material. Then, an upper portion of the insulating material may be planarized, thereby forming the buried insulating layer 112F.

Next, the processes described with reference to FIGS. 14A to 18 are performed. That is, the transistor TR1, the front wiring structure FWS, and the interlayer dielectric 162 may be formed on the first surface 110F of the substrate 110, and a portion of the substrate 110 may be removed from the second surface 110B of the substrate 110, thereby reducing the height of the substrate 110 in the vertical direction (Z direction).

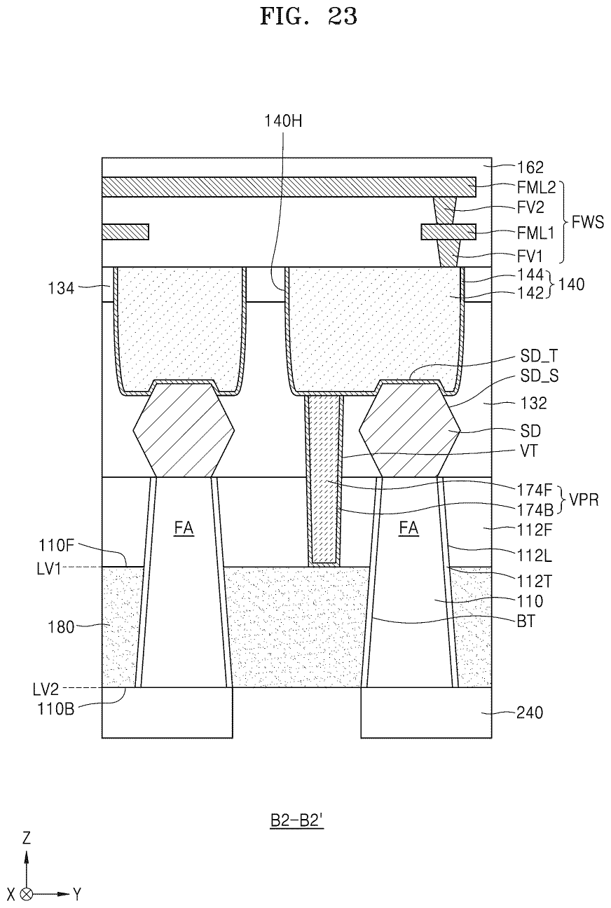

Referring to FIG. 23, a mask pattern 240 is formed on the bottom of the buried trench BT and the bottom surface of the sacrificial buried layer 180. Here, a portion of the sacrificial buried layer 180 and the second surface 110B of the substrate 110 may be covered by the mask pattern 240, and a portion of the sacrificial buried layer 180 may be exposed without being covered by the mask pattern 240. For example, two portions of the bottom surface of the sacrificial buried layer 180 are covered by the mask pattern 240, and a third portion of the bottom surface between the two portions is not covered by the mask pattern 240.

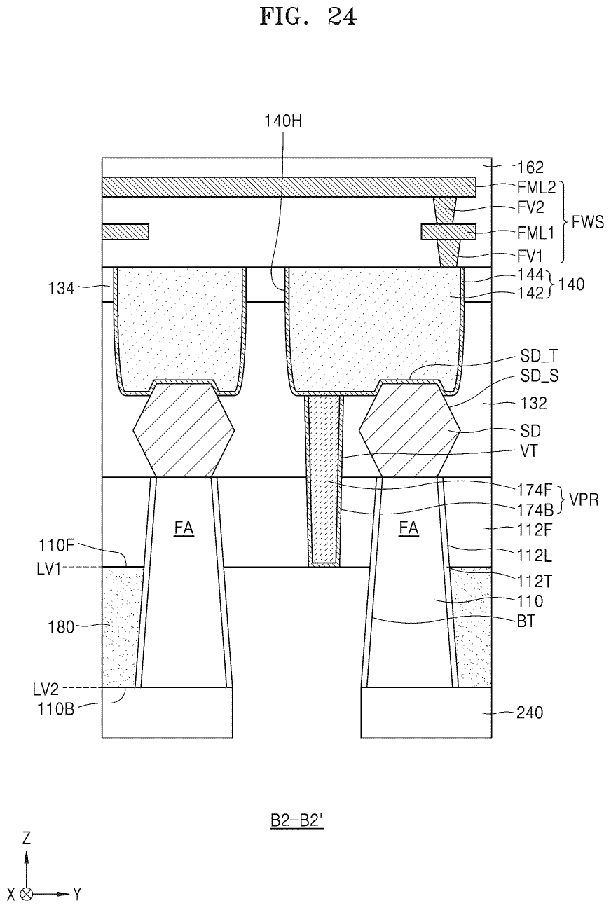

Referring to FIG. 24, the portion of the sacrificial buried layer 180, which is not covered by the mask pattern 240, may be removed. The bottom surface of the buried insulating layer 112F and the bottom surface of the power via VPR may be exposed by the removal of the sacrificial buried layer 180.

Referring again to FIGS. 6 and 7, the backside buried wiring layer BPR may be formed in the buried trench BT, and the backside wiring structure BWS and the backside interlayer dielectric 164 may be formed on the second surface 110B of the substrate 110.

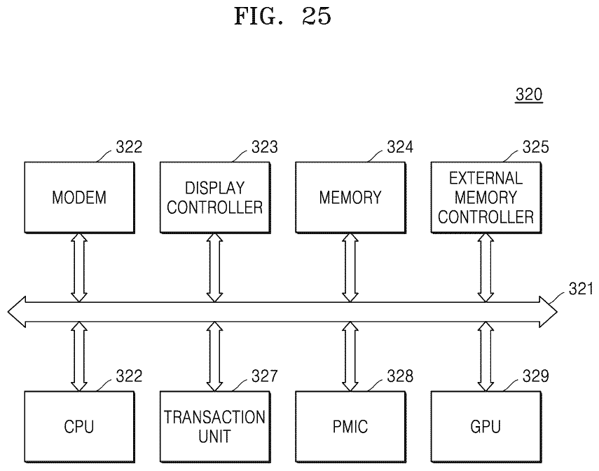

FIG. 25 is a block diagram illustrating a system-on-chip (SoC) 320 according to an embodiment. The SoC 320 may include, as a semiconductor device, an integrated circuit device (e.g., 100, 100A, and 200) according to an embodiment. The SoC 320 may be obtained by implementing complicated functional blocks, such as intellectual property (IP), which perform various functions, into one chip, and a standard cell and a power rail, according to an embodiment, may be included in each functional block of the SoC 320, thereby achieving the SoC 320 with an increased degree of integration and degree of freedom of routing.

Referring to FIG. 25, the SoC 320 may include a modem 322, a display controller 323, a memory 324, an external memory controller 325, a central processing unit (CPU) 326, a transaction unit 327 (e.g., a logic circuit), a power management integrated circuit (PMIC) 328, and a graphics processing unit (GPU) 329, and the respective functional blocks of the SoC 320 may communicate with each other through a system bus 321.

The CPU 326 capable of controlling overall operations of the SoC 320 may control operations of other functional blocks (that is, 322 to 329). The modem 322 may demodulate a signal received from outside the SoC 320 or may modulate a signal generated inside the SoC 320 and transmit the signal to the outside of the SoC 320. The external memory controller 325 may control operations of transmitting data to and receiving data from an external memory device connected to the SoC 320. For example, a program and/or data stored in the external memory device may be provided to the CPU 326 or the GPU 329 under control by the external memory controller 325. The GPU 329 may execute program instructions related to graphic processing. The GPU 329 may receive graphic data through the external memory controller 325 and may transmit graphic data, which is processed by the GPU 329, to the outside of the SoC 320 through the external memory controller 325. The transaction unit 327 may monitor data transactions of the respective functional blocks, and the PMIC 328 may control power supplied to each functional block, according to control by the transaction unit 327. The display controller 323 may transmit data generated inside the SoC 320 to a display by controlling the display (or a display device) outside the SoC 320.

The memory 324 may include nonvolatile memory, such as electrically erasable programmable read-only memory (EEPROM), flash memory, phase-change random access memory (PRAM), resistance random access memory (RRAM), nano-floating gate memory (NFGM), polymer random access memory (PoRAM), magnetic random access memory (MRAM), or ferroelectric random access memory (FRAM), or volatile memory, such as dynamic random access memory (DRAM), static random access memory (SRAM), mobile DRAM, double data rate synchronous dynamic random access memory (DDR SDRAM), low-power DDR (LPDDR) SDRAM, graphic DDR (GDDR) SDRAM, or Rambus dynamic random access memory (RDRAM).

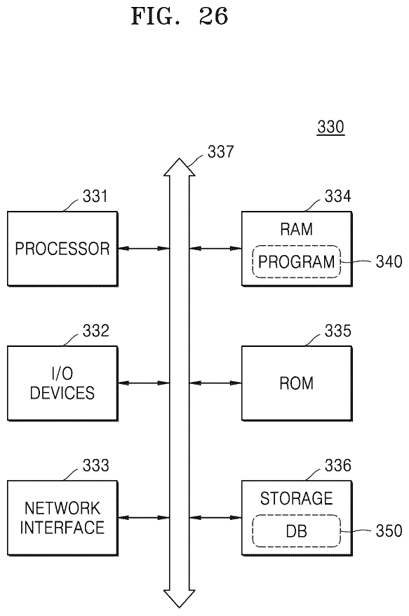

FIG. 26 is a block diagram illustrating a computing system 330 that includes a memory storing a program, according to an embodiment. At least some of the operations of the method of manufacturing an integrated circuit, according to an embodiment, may be performed by the computing system 330.

The computing system 330 may include a stationary computing system, such as a desktop computer, a workstation, or a server, or a portable computing system, such as a laptop computer. As shown in FIG. 26, the computing system 330 may include a processor 331, input/output devices 332, a network interface 333, RAM 334, ROM 335, and a storage device 336. The processor 331, the input/output devices 332, the network interface 333, the RAM 334, the ROM 335, and the storage device 336 may be connected to a bus 337 and may communicate with each other through the bus 337.

The processor 331 may be referred to as a processing unit and may include at least one core capable of executing any set of instructions (for example, Intel Architecture-32 (IA-32), 64-bit extended IA-32, x86-64, PowerPC, Sparc, MIPS, ARM, IA-64, or the like), such as a micro-processor, an application processor (AP), a digital signal processor (DSP), or a GPU. For example, the processor 331 may access memory, that is, the RAM 334 or the ROM 335, through the bus 337 and may execute instructions stored in the RAM 334 or the ROM 335.

The RAM 334 may store a program 340 for manufacturing an integrated circuit according to an embodiment or at least a portion of the program 340, and the program 340 may cause the processor 331 to perform at least some of the operations of the method of manufacturing an integrated circuit. That is, the program 340 may include a plurality of instructions capable of being executed by the processor 331, and the plurality of instructions of the program 340 may cause the processor 331 to perform a logic synthesis operation and/or a place and routing (P&R) operation.

The storage device 336 may be configured to retain data stored therein even when power supplied to the computing system 330 is cut off. For example, the storage device 336 may include a nonvolatile memory device or a storage medium, such as magnetic tape, an optical disk, or a magnetic disk. In addition, the storage device 336 may be detachable from the computing system 330. The storage device 336 may store the program 340 according to an embodiment, and the program 340 or at least a portion of the program 340 may be loaded into the RAM 334 from the storage device 336 before the program 340 is executed by the processor 331. Alternatively, the storage device 336 may store a file written in a program language, and the program 340, which is generated from the file by a compiler or the like, or at least a portion of the program 340 may be loaded into the RAM 334. In addition, as shown in FIG. 26, the storage device 336 may store a database 350, and the database 350 may include information used to design or manufacture an integrated circuit.

The storage device 336 may store data to be processed by the processor 331 or data processed by the processor 331. That is, the processor 331 may generate data by processing the data stored in the storage device 336 and may store the generated data in the storage device 336, according to the program 340.

The input/output devices 332 may include an input device, such as a keyboard or a pointing device, and an output device, such as a display device or a printer. For example, a user may trigger the execution of the program 340 by the processor 331 through the input/output devices 332.

The network interface 333 may provide access to a network external to the computing system 330. For example, the network may include a plurality of computing systems and communication links, and the communication links may include wired links, optical links, wireless links, or any other types of links.

While the inventive concept has been particularly shown and described with reference to embodiments thereof, it will be understood that various changes in form and details may be made therein without departing from the spirit and scope of the following claims.

What is claimed is:

1. A method of manufacturing an integrated circuit device, the method comprising:
forming a preliminary channel stack on a substrate comprising a first surface and a second surface opposite to the first surface, the preliminary channel stack comprising a plurality of sacrificial layers and a plurality of channel layers;
forming a preliminary channel pattern and a fin-type active region by removing a portion of the preliminary channel stack and a portion of the substrate, wherein a sidewall of the preliminary channel pattern and a sidewall of the fin-type active region are aligned with each other to define a buried trench;
forming a sacrificial buried layer in the buried trench;
forming a source/drain region on the fin-type active region;
forming a power via on the sacrificial buried layer, the power via being electrically connected to the source/drain region;
removing a portion of the substrate from the second surface of the substrate to expose a bottom surface of the sacrificial buried layer;
removing the sacrificial buried layer and forming a backside buried wiring layer in the buried trench, the backside buried wiring layer being electrically connected to the power via; and
forming a backside wiring structure on the second surface of the substrate, the backside wiring structure being electrically connected to the backside buried wiring layer.

2. The method of claim 1, further comprising:
conformally forming an insulating liner on a sidewall of the buried trench before the forming of the sacrificial buried layer; and
forming a buried insulating layer in the buried trench and on the sacrificial buried layer after the forming of the sacrificial buried layer.

3. The method of claim 2, wherein a portion of the insulating liner arranged on an inner wall of the buried trench is in contact with a sidewall of the backside buried wiring layer.

4. The method of claim 2, wherein the buried trench has an inclined sidewall, and
a first width of the buried trench at a level of the first surface of the substrate, is greater than a second width of the buried trench at a bottom surface of the buried trench.

5. The method of claim 2, further comprising:
forming a sacrificial gate electrode on the fin-type active region adjacent to the source/drain region after the forming of the sacrificial buried layer; and
forming an inter-gate dielectric to cover the sacrificial gate electrode and the source/drain region.

6. The method of claim 5, wherein the forming of the power via comprises:
forming a power via hole to expose an upper surface of the sacrificial buried layer by removing a portion of the inter-gate dielectric and a portion of the buried insulating layer;
forming the power via in the power via hole, the power via being in contact with the upper surface of the sacrificial buried layer;
forming a first contact hole to expose an upper surface of the source/drain region by removing a portion of the inter-gate dielectric; and
forming a first contact in the first contact hole, the first contact being in contact with an upper surface of the power via and the upper surface of the source/drain region.

7. The method of claim 5, wherein the forming of the preliminary channel pattern and the fin-type active region to define the buried trench comprises:
forming the preliminary channel pattern and the fin-type active region to define a device isolation trench having a first depth, by removing a portion of the preliminary channel stack and a portion of the substrate; and
forming the buried trench having a second depth, by removing a portion of the substrate exposed at a bottom of the device isolation trench.

8. The method of claim 1, wherein the sacrificial buried layer comprises silicon nitride or silicon oxynitride.

9. The method of claim 1, wherein the fin-type active region comprises a plurality of fin-type active regions extending in a first horizontal direction,
the plurality of fin-type active regions comprise a first fin-type active region and a second fin-type active region adjacent to each other in a second horizontal direction, and
the sacrificial buried layer is arranged between the first fin-type active region and the second fin-type active region, in a plan view.

10. The method of claim 9, wherein the forming of the power via comprises forming the power via between a first source/drain region and a second source/drain region, the first source/drain region positioned on one side of the first fin-type active region, and the second source/drain region positioned on one side of the second fin-type active region.

11. A method of manufacturing an integrated circuit device, the method comprising:
forming a device isolation trench by removing a portion of a substrate, and forming a fin-type active region from the substrate to extend in a first horizontal direction, wherein the substrate comprises a first surface and a second surface opposite to the first surface;
forming a buried trench by removing a portion of the substrate at a bottom of the device isolation trench, wherein a sidewall of the buried trench is aligned with a sidewall of the fin-type active region;
forming a sacrificial buried layer on in the buried trench;
forming a gate electrode on the fin-type active region to extend in a second horizontal direction intersecting with the first horizontal direction;
forming a source/drain region on the fin-type active region, which is arranged on one side of the gate electrode;
forming a power via on the sacrificial buried layer, the power via being electrically connected to the source/drain region;
removing a portion of the substrate from the second surface of the substrate to expose a bottom surface of the sacrificial buried layer;
removing the sacrificial buried layer and forming a backside buried wiring layer in the buried trench, the backside buried wiring layer being electrically connected to the power via; and
forming a backside wiring structure on the second surface of the substrate, the backside wiring structure being electrically connected to the backside buried wiring layer.

12. The method of claim 11, further comprising:
conformally forming an insulating liner on a sidewall of the buried trench before the forming of the sacrificial buried layer; and
forming a buried insulating layer in the buried trench and on the sacrificial buried layer.

13. The method of claim 12, wherein a portion of the insulating liner arranged on an inner wall of the buried trench is in contact with a sidewall of the backside buried wiring layer.

14. The method of claim 12, wherein the buried trench has an inclined sidewall, and
a first width of the buried trench at a level of the first surface of the substrate, is greater than a second width of the buried trench at a bottom surface of the buried trench.

15. The method of claim 12, further comprising forming an inter-gate dielectric to cover the gate electrode and the source/drain region.

16. The method of claim 15, wherein the forming of the power via comprises:
forming a power via hole to expose an upper surface of the sacrificial buried layer by removing a portion of the inter-gate dielectric and a portion of the buried insulating layer;
forming the power via in the power via hole, the power via being in contact with the upper surface of the sacrificial buried layer;
forming a first contact hole to expose an upper surface of the source/drain region by removing a portion of the inter-gate dielectric; and
forming a first contact in the first contact hole, the first contact being in contact with an upper surface of the power via and the upper surface of the source/drain region.

17. The method of claim 15, wherein the fin-type active region comprises a plurality of fin-type active regions extending in a first horizontal direction,
the plurality of fin-type active regions comprise a first fin-type active region and a second fin-type active region adjacent to each other in a second horizontal direction, and
the sacrificial buried layer is arranged between the first fin-type active region and the second fin-type active region, in a plan view.

18. The method of claim 17, wherein the forming of the power via comprises forming the power via between a first source/drain region and a second source/drain region, the first source/drain region positioned on one side of the first fin-type active region, and the second source/drain region positioned on one side of the second fin-type active region.

19. A method of manufacturing an integrated circuit device, the method comprising:
forming a preliminary channel stack on a substrate comprising a first surface and a second surface opposite to the first surface, the preliminary channel stack comprising a plurality of sacrificial layers and a plurality of channel layers;
forming a preliminary channel pattern and a fin-type active region by removing a portion of the preliminary channel stack and a portion of the substrate to form a device isolation trench;
forming a buried trench by removing a portion of the substrate at a bottom of the device isolation trench, wherein a sidewall of the buried trench is aligned with a sidewall of the fin-type active region;
forming an insulating liner on an inner wall of each of the device isolation trench and the buried trench;
forming a sacrificial buried layer in the buried trench, wherein the sacrificial buried layer is not positioned on the inner wall of the device isolation trench;
forming a buried insulating layer on the sacrificial buried layer and on the inner wall of the device isolation trench;
forming a source/drain region on the fin-type active region;
forming a power via on the sacrificial buried layer, the power via being electrically connected to the source/drain region;
removing a portion of the substrate from the second surface of the substrate to expose a bottom surface of the sacrificial buried layer;
removing the sacrificial buried layer and forming a backside buried wiring layer in the buried trench, the backside buried wiring layer being electrically connected to the power via; and
forming a backside wiring structure on the second surface of the substrate, the backside wiring structure being electrically connected to the backside buried wiring layer.

20. The method of claim 19, further comprising:
forming a sacrificial gate electrode on a portion of the fin-type active region adjacent to the source/drain region after the forming of the sacrificial buried layer; and
forming an inter-gate dielectric to cover the sacrificial gate electrode and the source/drain region,
wherein the forming of the power via comprises:
forming a power via hole to expose an upper surface of the sacrificial buried layer by removing a portion of the inter-gate dielectric and a portion of the buried insulating layer;
forming the power via in the power via hole, the power via being in contact with the upper surface of the sacrificial buried layer;
forming a first contact hole to expose an upper surface of the source/drain region by removing a portion of the inter-gate dielectric; and
forming a first contact in the first contact hole, the first contact being in contact with an upper surface of the power via and the upper surface of the source/drain region.
